(19) United States
(12) Patent Application Publication
(10) Pub. No.: US 2009/0183774 A1
(43) Pub. Date: Jul. 23, 2009

(54) Thin Film Semiconductor-on-Sapphire Solar Cell Devices

(75) Inventor: Petar B. Atanackovic, Henley Beach (AU)

Correspondence Address: FERNANDEZ & ASSOCIATES LLP, 1047 EL CAMINO REAL, SUITE 201, MENLO PARK, CA, 94025, US

(73) Assignee: Translucent, Inc., Palo Alto, CA (US)

(21) Appl. No.: 12/171,200

(22) Filed: Jul. 10, 2008

Related U.S. Application Data
(60) Provisional application No. 60/949,753, filed on Jul. 13, 2007.

(51) Int. Cl. H01L 31/00

(52) U.S. Cl. 136/261

(57) ABSTRACT

The present invention relates to semiconductor devices suitable for electronic, optoelectronic and energy conversion applications. In a particular form, the present invention relates to the fabrication of a thin film solar energy conversion device and wafer scale module through the combination of single crystal semiconductors, insulators, rare-earth based compounds and sapphire substrates. The use of thin film silicon allows large change in optical absorption co-efficient as a function of wavelength to be optimized for solar cell operation. New types of solar cell devices are disclosed for use as selective solar radiation wavelength absorbing sections to form multi-junction device and exceed single junction limit, without the use of different band gap semiconductors. A method for concentrating and/or recycling solar optical radiation within the active semiconductor layers is also disclosed to form a 1+-sun concentrator solar cell via the use of sapphire substrate and advantageously positioned planar reflector.

### PRIORITY

The present application claims priority from Provisional application 60/949,753 filed on Jul. 13, 2007.

### CROSS REFERENCE TO RELATED APPLICATIONS

Applications and patents Ser. Nos. 09/924,392, 10/666,897, 10/746,957, 10/799,549, 10/825,912, 10/825,974, 11/022,078, 11/025,363, 11/025,680, 11/025,681, 11/025,692, 11/025,693, 11/084,486, 11/121,737, 11/187,213, U.S. 20050166834, U.S. 20050161773, U.S. 20050163692, Ser. Nos. 11/053,775, 11/053,785, 11/054,573, 11/054,579, 11/054,627, 11/068,222, 11/188,081, 11/253,525, 11/254,031, 11/257,517, 11/257,597, 11/393,629, 11/398,910, 11/472,087, 11/788,153, 11/960,418, 12/119,387, 60/820,438, 60/811,311, 60/847,767, 60/944,369, 60/949,753, U.S. Pat. No. 7,018,484, U.S. Pat. No. 7,037,806, U.S. Pat. No. 7,135,699, U.S. Pat. No. 7,199,015, all held by the same assignee, contain information relevant to the instant invention and are included herein in their entirety by reference. References, noted at the end, are included herein in their entirety by reference.

### BACKGROUND OF INVENTION

1. Field of the invention

The present invention relates to fabrication of solar cells through various combinations of rare-earths, rare-earth oxides, nitrides, phosphides and carbides and Group IV, III-V, and II-VI semiconductors and alloys thereof; thin films are disposed upon low cost substrates.

2. Related Art

U.S. Pat. No. 3,413,145, U.S. Pat. No. 3,393,088, U.S. Pat. No. 5,374,564, U.S. Pat. No. 7,037,806, U.S. Pat. No. 6,372,609, U.S. Pat. No. 6,100,166, U.S. Pat. No. 7,018,484, U.S. Pat. No. 5,686,734, U.S. Pat. No. 7,022585, U.S. Pat. No. 7,327,036, U.S. Pat. No. 7,390,962, U.S. 2004/0103937, U.S. 2008/0057616, U.S. 2008/0096374, and U.S. 2008/0121280 contain information relevant to the instant invention and are included herein in their entirety by reference.

It is an aspect of the present invention to solve the deficiencies of prior art thin film solar cells disposed upon substrates via the use of semiconductor thin films deposited upon substrates, optionally, single crystal or not.

### SUMMARY OF THE INVENTION

The present invention relates to semiconductor devices suitable for electronic, optoelectronic and energy conversion applications. In some embodiments, the present invention relates to fabrication of a thin film solar energy conversion devices and, optionally, wafer scale modules through advantageous combination of single crystal semiconductors, insulators, rare-earth based compounds and sapphire substrates. Crystalline and polycrystalline thin, semiconductor film(s) formed on sapphire substrate is disclosed. Example embodiments of crystalline or polycrystalline thin film semiconductor-on-sapphire formation using silicon and impurity doped layer(s) are disclosed. In particular, thin film silicon-on-sapphire solar cell device configurations are disclosed as optional embodiments, wherein a single, and/or, poly, crystalline sapphire substrate is utilized as a multi-functional solution for: (i) crystalline surface for Si epitaxy; (ii) providing robust environmental packaging; (iii) optically transparent medium for coupling broad band solar radiation into a semiconductor active region; (iv) high thermal conductivity substrate; and (v) low cost of manufacture.

The use of thin film silicon allows the large change in optical absorption co-efficient as a function of wavelength to be optimized for solar cell operation. New types of solar cell devices based on metal-insulator-semiconductor-sapphire (MISS), metal-semiconductor-insulator-semiconductor-sapphire (MSISS) are disclosed for adsorption of the high energy portion of the solar spectrum. New types of silicon-on-sapphire devices based on optical power conversion in multi-layer structures, such as, p-n, p-i-n, p-i-n-i-p, p-i-n-p-i-n and various combinations thereof, using impurity doping of Si are also disclosed. An example embodiment discloses a stacked p-i-n-p-i-n device with different thickness intrinsic region optimized for absorbing different portions of the solar spectrum. Hybrid solar cell devices based upon MIS/PIN are also disclosed for use as selective solar radiation wavelength absorbing sections to form multijunction devices and thus exceed single junction limit, without the use of different band gap semiconductors. A method for concentrating and/or recycling solar optical radiation within active semiconductor layers is also disclosed to form a 1+sun concentrator solar cell via the use of a transparent sapphire substrate and advantageously positioned planar reflector. An optional embodiment of the present invention is the manufacture of thin film semiconductor-on-sapphire suitable for high performance thin film solar energy conversion devices.

Of interest are binary single crystal alkali-metal oxides (AMOₓ), for example, sodium-oxide (Na₂O) and lithium oxide (Li₂O). Alkali-ions are typically deleterious in semiconductor device fabrication owing to the high diffusivity. The alkali-metal oxides have been well understood to advantageously participate and dictate alkali-silicate glass formation and properties, such as sodium-silicate glass (Na₂O)ₓ(SiO₂)₁₋ₓ. However, specific electronic properties of isolated AMOₓ compounds are sparse. Unlike the well understood alkali-earth metal oxides (AEOₓ), the binary alkali-metal oxides have not been examined in detail as isolated single crystal forms. That is, single crystal Na₂O and Li₂O thin films or bulk forms have not been fully investigated. Of particular interest is the crystal structure and electronic properties of alkali-oxides. Recent data on Na₂O and Li₂O polycrystalline powders show they crystallize in anti-fluorite structures with excellent stability and form a new class of superionic insulators. The cubic lattice constant of Na₂O is a₀₀₁(Na₂O)=5.481 Å, and is well suited to thin film epitaxial growth on (001)-oriented Si surfaces, having a lattice const. a₀₀₁(Si)=5.431 Å. The fundamental electronic band gap of (AMOₓ) is known to exceed E_{g}>6 eV (where A={Na, Li}, x≈0.5), and be indirect in nature for single crystals of Na₂O and Li₂O. It is anticipated that the alkali-metal oxides may be technologically useful in single crystal forms of dielectric or insulating layers suitable for the present invention. However, it is noted that the alkali-oxides may have a high affinity for and/or reactivity with water. This may be useful in layer separation and/or transfer techniques, as disclosed in a recent provisional patent application U.S. 60/944,369.

### BRIEF DESCRIPTION OF THE FIGURES

FIG. 1 shows the absorption coefficient α_{abs} of single crystal (Si) and (Ge).

FIG. 2 shows insulating and transparent substrates exemplary of the invention.

FIG. 3 shows one example solar device and/or module fabrication steps.

FIG. 4 shows a bulk or unstrained sapphire crystal.

FIG. 5A: (001)-oriented bulk Si unit cell 504; FIG. 5B: sapphire R-plane; FIG. 5C: schematically depicts unit cell dimensions of (001)-oriented Si and R-plane Al₂O₃.

FIG. 6A: steps for depositing a Si epi-layer upon a R-plane sapphire substrate. FIG. 6B: a high resolution electron microscope image of a typical Si epi-layer grown directly upon an R-plane sapphire substrate.

FIG. 7 discloses processing steps for an epitaxially grown stacked layer(s).

FIGS. 8A and 8B disclose two types of buffer layers.

FIG. 9: methods for improving structural quality of interfacial defective region.

FIG. 10 shows semiconductor-on-sapphire structures for solar cell fabrication.

FIG. 11: process steps for converting a defective semiconductor region into an amorphous and/or insulating and/or transparent layer.

FIG. 12: single crystal sapphire substrate prepared for epitaxy of semiconductor forming defective layer and a low defect portion.

FIG. 13 discloses multilayer structure used for manufacture of solar cell device.

FIG. 14: lowest energy indirect band gap E_{g} and direct band gap E_{Γ1} for Si.

FIG. 15A shows a semiconductor-insulator-semiconductor (SIS) or metal-insulator-semiconductor (MIS) device fabricated upon a sapphire substrate.

FIG. 15B shows a MIS SoS equivalent circuit.

FIG. 16A: SoS solar cell based on SIS structure disposed upon a substrate; FIG. 16B: energy band structure versus vertical dimension through multilayer stack structure.

FIG. 17A: SoS solar cell devices based on SIS structure disposed upon a substrate; FIG. 17B: (SIS) or (MIS) device fabricated upon a sapphire substrate.

FIGS. 18A and B show optional embodiments of MIS SoS solar cell devices.

FIG. 19A: an example p-i-n SoS embodiment; FIG. 19B: equivalent circuit is represented by a p-i-n diode.

FIG. 20A shows multiple lateral p-i-n devices fabricated on a SoS substrate; FIG. 20B equivalent circuit where p-i-n devices are series connected.

FIG. 21A shows a stacked layer structure comprising two p-i-n diodes comprising different intrinsic absorber thicknesses; FIG. 21B shows generation rate G(λ, z) of electron-hole pairs as a function of vertical distance, z, through a layered structure.

FIGS. 22A and 22B show optional wavelength bands used for an example tandem Si p-i-n-p-i-n solar cells.

FIG. 23: MIS/PIN hybrid wherein the MIS section is a short wavelength converter.

FIG. 24: epitaxial semiconductor layer thickness L_{Si} required to form FD-SoS as a function of the effective impurity concentration.

FIGS. 25A and 25B disclose the optical tunability of the Si absorption spectrum by the choice of the Si layer thickness L_{Si}.

FIG. 26 discloses schematic influence on efficiency due to reflection co-efficient of rear surface, for a double pass solar cell.

FIG. 27 discloses the use of a diffractive grating and/or element positioned at the rear portion of the semiconductor layer.

FIG. 28 discloses the diffractive effect incorporated into a p-i-n solar cell disposed upon a sapphire substrate.

FIG. 29 shows the effect of two different wavelengths λ being separated from broad band solar radiation by diffractive element.

FIG. 30 shows the broad band solar radiation 2820 incident upon a device.

FIG. 31 discloses the use of multilayer guided wave structures.

FIG. 32: variation of incident solar radiation angle to the sapphire substrate.

FIG. 33: a process for manufacture of semiconductor on rare-earth based layer.

FIG. 34 shows an exemplary implant and subsequent treatment.

FIG. 35 shows detail of further modification of compound structure.

### DETAILED DESCRIPTION OF THE INVENTION

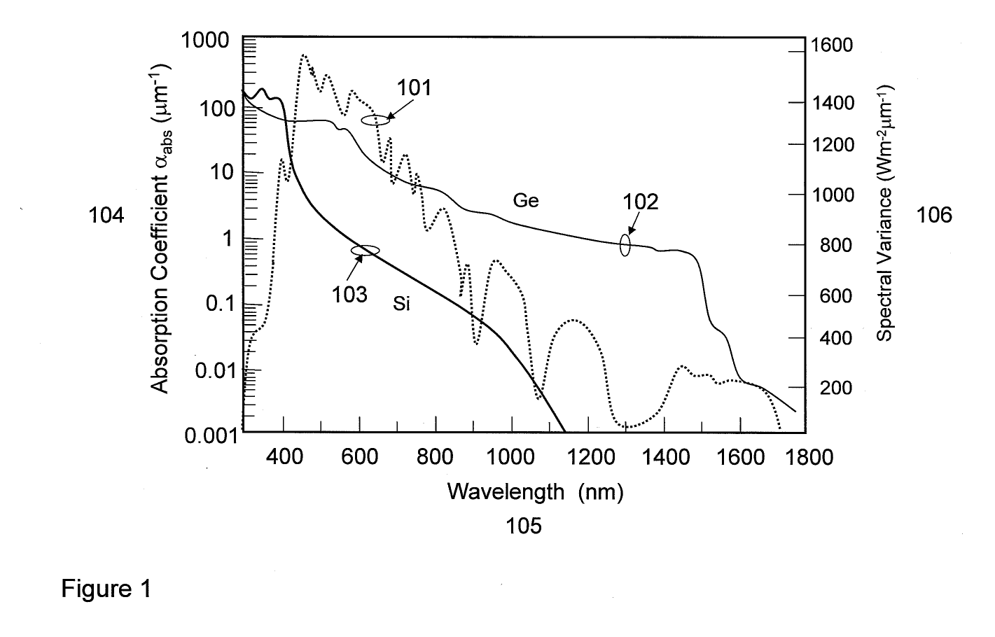

The broadband solar optical spectrum at ground level spans wavelengths (λ) from 300 nm to over 1700 nm, covering the ultraviolet (UV) to far infrared (IR). FIG. 1 shows a general solar power spectrum 101, the absorption coefficient α_{abs} 104 of single crystal silicon (Si) 103 and germanium (Ge) 102 as a function of wavelength. Peak spectral variance 106 occurs at λ_{P}˜496 nm (˜2.5 eV) in the 400<λ<600 nm region. FIG. 1 shows the indirect band gap semiconductors Si and Ge span major portions of the solar spectrum. Ge exhibits 10-100× higher absorption co-efficient than Si in the 1.1-3 eV range. This indicates 10-100× thinner film absorbers using Ge are possible compared to Si. The use of Ge also extends absorption down to 0.66 eV and therefore accesses more of the available solar spectrum and available power.

Prior art thin film Si solar cells disposed upon insulating and transparent substrates using direct Si deposition methods have been limited to amorphous substrates, e.g., glass and/or polymers. The present invention solves the deficiencies of prior art thin film Si solar cell technologies by the use of new forms of insulating and transparent substrates. Specifically, substrates possessing the properties of: (i) crystalline structure and compatibility with direct deposition of single crystal Si; and (ii) radiative transparency to solar radiation; and (iii) electrically insulating.

In an embodiment a polycrystalline sapphire (Al₂O₃) substrate is used. In an optional embodiment a single crystal sapphire (Al₂O₃) substrate is used. In another optional embodiment a single crystal sapphire (Al₂O₃) substrate is used with at least one of a: (i) cubic R-plane surface; (ii) C-plane oriented surface; (iii) A-plane oriented surface; (ii) M-plane oriented surface; and/or other textured or multi-oriented surfaces. In various embodiments of the present invention substrate compositions are chosen from a group comprising sapphire, diamond (C₄), calcium fluoride (CaF₂), zircon (ZrₓSi₁₋ₓO₄), zinc oxide (ZnO), aluminum nitride (AlN), wide band gap compositions comprising binary single crystal alkali-metal oxides (AMOₓ), for example, sodium-oxide (Na₂O) and lithium oxide (Li₂O); optionally, these materials may form dielectric or insulating layers, single crystalline or not, in a radiation generating or converting device of the present invention. Gallium arsenide (GaAs), gallium-indium-phosphide (GaInP), copper-indium-gallium-selenide (CIGS) and cadmium-telluride/sulphide (CdTe/CdS) compounds can also be disposed on cost effective substrates, such as glass, using the present invention. An advantage of using wider band gap energy materials is the cell voltage may increase and thus develop a large open circuit voltage.

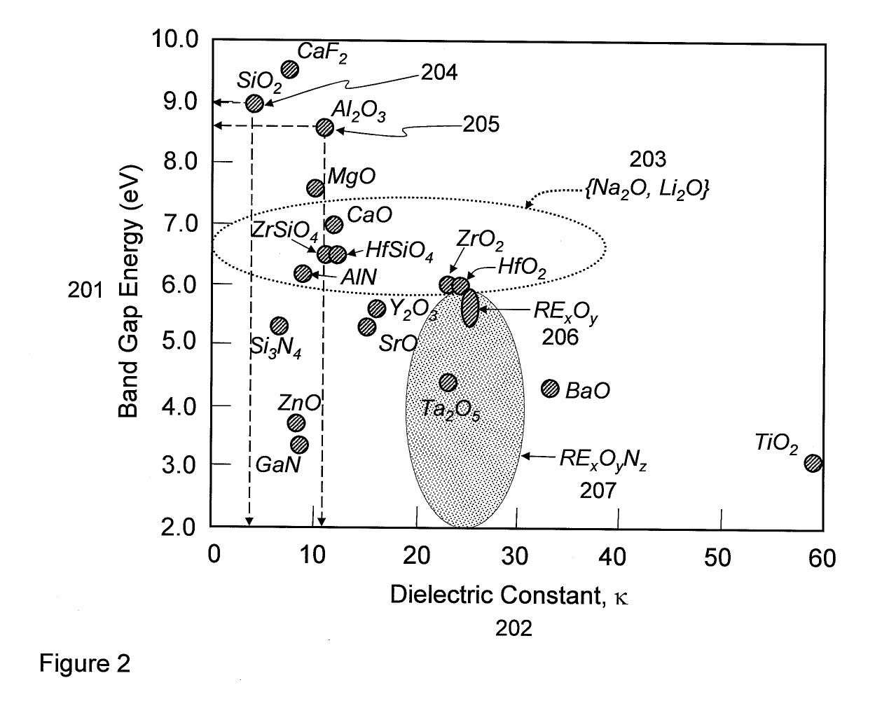

FIG. 2 discloses a selection, but not limited to, types of insulating and transparent substrates suitable for implementing the present invention. The fundamental energy band gap 201 of the material is plotted as a function of the dielectric constant 202. Several materials are known to crystallize in single crystal forms, namely, aluminum oxide or sapphire (Al₂O₃), calcium fluoride CaF₂, alkaline-earth metal oxides (e.g., MgO, SrO), aluminum-nitride (AlN), gallium nitride (GaN). Less well known are the single crystal forms of the rare-earth oxides 206 and rare-earth oxynitrides 207 (REₓO_{y} and REₓO_{y}N_{z}. The REₓO_{y}N_{z} 207 alloys can be continuously tuned from ˜6 eV using binary REₓO_{y} down to semi-metallic E_{g}˜0 eV (not shown below E_{g}<2 eV) for the rare-earth nitrides (REN).

RE is chosen from at least one of the rare earth or lanthanide series from the periodic table of elements comprising {⁵⁷La, ⁵⁸Ce, ⁵⁹Pr, ⁶⁰Nd, ⁶¹Pm, ⁶²Sm, ⁶³Eu, ⁶⁴Gd, ⁶⁵Tb, ⁶⁶Dy, ⁶⁷Ho, ⁶⁸Er, ⁶⁹Tm, ⁷⁰Yb and ⁷¹Lu}; additionally, yttrium 39Y is included as well for the invention herein.

Additional candidate materials, not widely known or researched, are the alkaline-metal oxides (e.g., Na₂O, Li₂O). Amorphous silicon dioxide 204 (SiO₂) is one of the most intensely researched materials, possessing extremely large band gap E_{g}(SiO₂)˜9 eV, relatively low dielectric constant and excellent structural and electronic interface formation with Si. High quality SiO₂ films can be thermally grown on Si and/or deposited. SiO₂ also naturally occurs abundantly in the earths crust and is widely used in glass formation. Alkali-silicate glass, e.g. (Na₂O)ₓ(SiO₂)₁₋ₓ, is also a major industrial material.

In comparison to amorphous SiO₂, the corundum form and/or single crystal aluminum oxide 205 also posses a very wide band gap E_{g}(Al₂O₃)˜8.8 eV, with ˜3× higher dielectric constant. Single crystal sapphire substrates are commercially available and can be manufactured in a variety of surface crystal orientations suitable for direct epitaxy of substantially single crystal semiconductor materials.

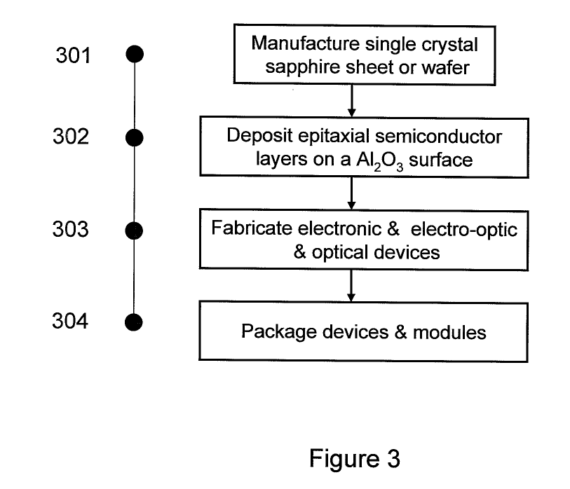

FIG. 3 describes optional process steps disclosed by the present invention for the manufacture of high efficiency solar cell and/or module using semiconductor-on-sapphire (SoS) structures. As used herein SoS refers to a structure comprising a semiconductor, optionally, silicon, layer and a sapphire substrate; a semiconductor layer may comprise a layer of high defect density and low long range order and a layer of low defect density and high long range order; a sapphire substrate may comprise a portion of high alkali impurities and a portion of very low alkali impurities.

In this embodiment, Step 301 provides single crystal sapphire in wafer and/or sheet form. A clean single crystal sapphire surface of definite crystal symmetry enabling direct epitaxy is prepared. Thin film, single crystal semiconductor layers are deposited upon sapphire substrate, step 302, comprising electrical and/or electro-optical and/or passive optical layers. Layered semiconductors and/or insulators and/or rare-earth based compounds are then fabricated into solar cells, step 303 and then wafer and/or sheet is assembled and packaged, step 304.

Optionally, R-plane single crystal sapphire is used and direct Si epitaxy is performed via CVD process at growth temperatures in the range 300°<T_{g} (Si)<1500° C. Optionally, substantially C-plane, A-plane, or M-plane sapphire surfaces may also be used for thin film semiconductor deposition and is also disclosed for use in the present invention for solar cell manufacture. Optionally, vicinal and/or miscut surfaces may be utilized for optimizing the film deposition properties.

It is anticipated that high volume and low cost sapphire substrates can be manufactured via large diameter bulk CZ boules (>15″diam.) and/or by direct manufacture of large form factor sheet produced by an EFG process and currently offered by Saint-Gobain of France, Sapphikon, Inc. of Nashua, N.H. and RSA LeRubis S A [rubisrsa.com (Jun. 26, 2007)] and disclosed in U.S. Pat. No. 5,702,654, included herein in its entirety by reference. As the sapphire CZ and EFG, edge-fault-growth, crystal growth processes are similar to that for Si, it is expected that sapphire costs can be kept low. In some embodiments the instant invention comprises a substrate of sapphire produced from bauxite ore crystallized in sheet form, optionally crystallized bauxite with an optional intervening barrier layer to prevent diffusion of at least deleterious species or impurities into a semiconductor layer and one or more layers of single crystal semiconductor layers thereon enabling a device for conversion of radiation into electricity. As used herein a barrier layer functionally impedes deleterious species from a substrate reaching an active layer and impairing operation of a device.

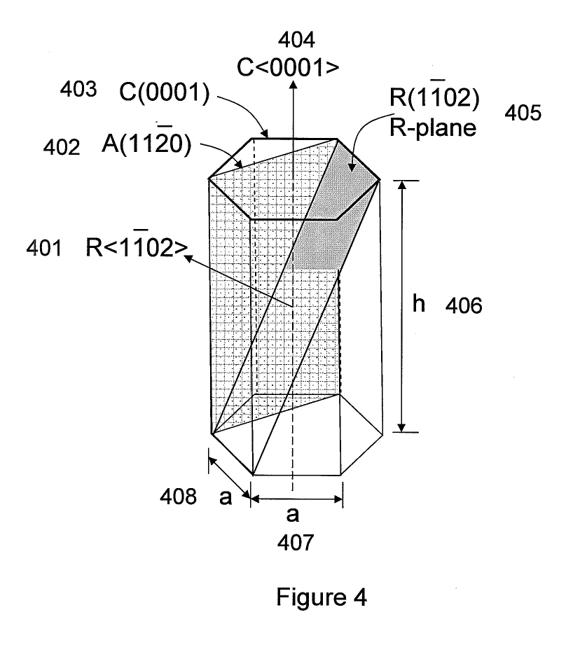

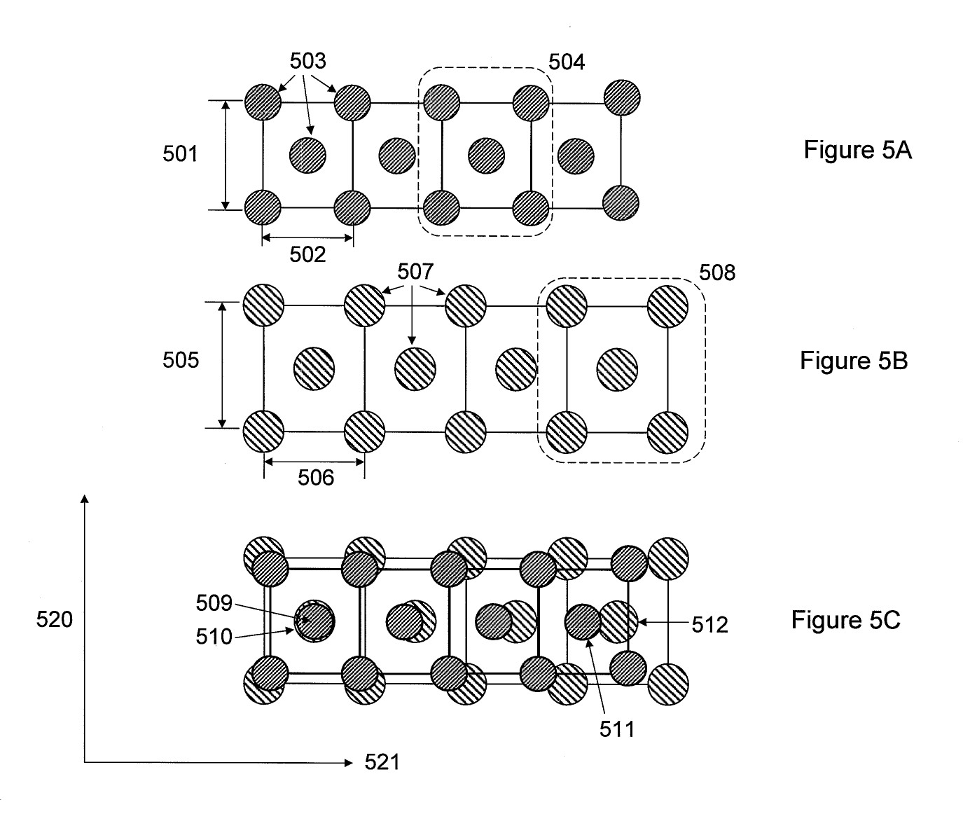

A bulk or unstrained sapphire crystal is shown in FIG. 4, with hexagonal symmetry along the c-axis, with sides of length, a, shown as 407 & 408, and height, h 406. Due to the hexagonal symmetry, a sapphire crystal can be described using hexagonal coordinates, such that the C-axis of sapphire is written as (0001). A sapphire crystal exhibits a trigonal space group (167) and can be dissected into the commonly known C-plane 403, A-plane 402 and R-plane 405, as well as others. The C-plane 403 has hexagonal symmetry useful for deposition of wurtzite type structures, such as GaN, AlN, and ZnO. In an example embodiment, but not limited to, is the present invention's disclosure of optional use of the R-plane surface 405 exhibiting tetragonal symmetry. The R-plane 405 has normal to the plane 401 with aluminum (Al) atoms 503 arranged in an R-plane as shown in FIG. 5A. The R-plane Al atom spacing 501 (˜4.76 Å) along the (1120) direction 520 and 502 (˜5.20 Å) along the (1101) direction 521. Similarly, the (001)-oriented bulk Si unit cell 508 is shown in FIG. 5b, where the Si atom 507 lattice spacing 505 and 506 are equal to 5.431 Å. For direct Si epitaxy upon the R-plane surface, there is a lattice mismatch of 4.2% along the (1101) direction and a lattice mismatch of 12.5% along the (1120) direction. FIG. 5C schematically depicts the difference in free standing unit cell dimensions between (001)-oriented Si and R-plane Al₂O₃. This lattice mismatch and the thermal expansion mismatch between sapphire crystal and silicon crystal lead to crystalline defects (twins and dislocations) in a silicon epi-layer, detrimentally affecting electronic device performance.

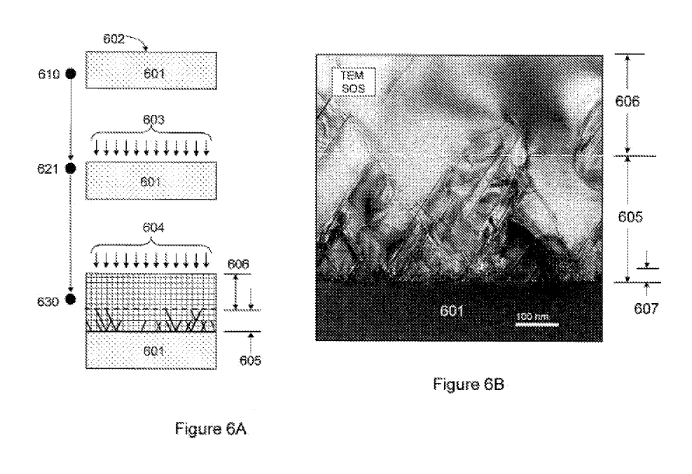

The difference in crystalline structure and symmetry between Si and sapphire results in strained layer hetero-epitaxy. The Si film is distorted tetragonally due to the dissimilarity in free standing lattice constants. Beyond a critical layer thickness a single crystal silicon film partially relaxes and recovers structural quality, as shown in FIG. 6B region 606.

FIG. 6A shows examplary steps for directly depositing a Si epi-layer upon a R-plane sapphire substrate. The sapphire surface 602 is clean, free from particulate contamination and is preferably aluminum terminated. Silane 603 is decomposed upon the heated substrate 601. The Si film initially grows with high concentration of defects and twins near the Si/Al₂O₃ interface 605 and decreases in a direction into silicon layer 606, away from the Si/Al₂O₃ interface. FIG. 6B shows a high resolution electron microscope image of a typical Si epi-layer grown directly upon an R-plane sapphire substrate. The high number of misfit dislocations, Si twins and structural defects are clearly evident in the region 607 in the immediate vicinity of the Si/Al₂O₃ interface, evolving to predominately elongated twin defects 605, and becoming essentially free of defects in region 606.

An alternate embodiment begins with an Al₂O₃ substrate; then a layer of a rare-earth material is deposited as a transition or buffer and/or barrier layer; next a semiconductor, optionally silicon, layer is deposited. In this manner an inexpensive Al₂O₃ substrate is employed. The RE layer serves not only as a transition layer to a silicon layer but also as a blocking or barrier layer for any contaminates in the Al₂O₃ substrate, preventing them from out gassing or diffusing into the silicon layer. Once a high quality silicon layer is achieved on a substrate numerous integrated circuit type devices, including solar cells, can be fabricated. A similar concept can be applied to a silicon substrate wherein a rare-earth layer is deposited on silicon and used to transition to a GaN or III-V based material system for light emitting structures. A novelty here is that a rare-earth based material system can be used to transition from a hexagonal crystal structure such as found in alumina to a cubic structure found in silicon; alternatively a rare-earth based material system can be used to transition from a cubic structure found in silicon to a hexagonal crystal structure such as found in alumina or III-V compounds. A rare-earth based material system comprises rare-earth metals combined with other elements chosen from a group comprising oxygen, nitrogen, phosphorus, carbon, silicon, and germanium. In some embodiments a rare-earth based material system transitions from one composition adjacent to a hexagonal structure based substrate to a different composition adjacent to a cubic structure based layer in order to minimize lattice strain and facilitate a high quality single crystal deposited structure. Alternatively, with a cubic structure based substrate, a rare-earth based material system transitions from one composition next to the substrate to a different composition adjacent to a hexagonal structure based deposited layer.

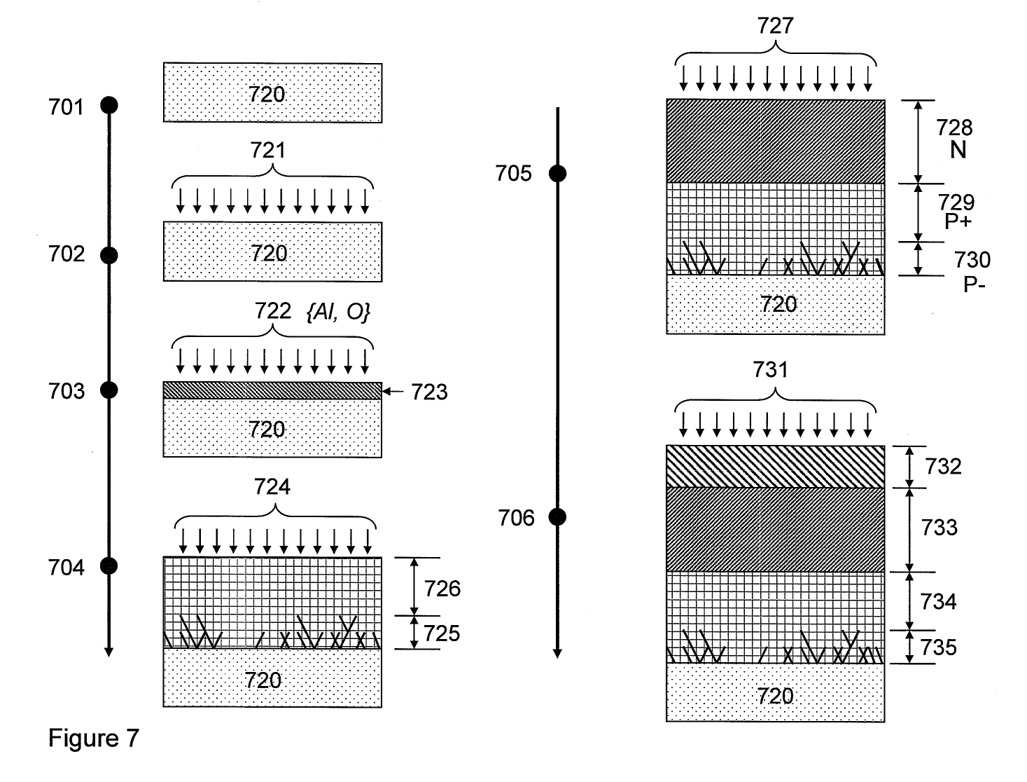

FIG. 7 discloses processing steps for fabricating an epitaxially grown stacked layer sequence. For example a Si p-n homojunction solar cell can be realized. A single crystal sapphire substrate 720 is cleaned, step 702, with reactants 721 to remove surface contamination. It is found that high temperature annealing in H_{2(g)} or O_{2(g)} atmosphere advantageously prepares the surface. For the case of annealing in an O_{2(g)} and/or atomic oxygen atmosphere 703, an oxygen-terminated surface can result. Alternatively, at least one or more Al layer(s) 723 can be deposited in order to form an Al-terminated surface. Alternatively, at least one or more oxygen layer(s) 723 can be deposited or removed in order to form an O-terminated surface.

Another optional embodiment is the oxidation of epitaxially deposited Al surface layer to form a single crystal Al₂O₃ buffer layer, noted as 723. Another optional embodiment is the co-deposition, optionally, sequential, of Al and oxygen species 722 upon the sapphire surface to form a high quality buffer layer 723. The optional buffer layer 723 is advantageous for creating a high quality and flat surface to commence Si epi-layer deposition.

Step 704 uses Si precursors 724 and high substrate temperature to deposit a thick Si epilayer exceeding the thickness where twin defects are localized 725. The region 726 is relatively defect-free. Twin defects are typical p-type in character, and can be enhanced via the co-deposition of p-type impurity atoms during growth. Alternatively, a region 725 can be grown and not-intentionally doped (NID), followed by an optionally p-type doped layer 726. Next, step 705 deposits an n-type Si epi-layer 728 using Si and n-type impurity species 727. The structure thus formed is a vertical p⁻-p⁺-n⁺ solar cell diode. The depletion layer formed between the p⁺-n⁺ junction is used for optical absorption of greater than band gap solar photons to create photo-generated charge carriers, i.e., electron and hole pairs. For indirect band gap Si, the photo-generated electron-hole pairs do not efficiently recombine radiatively, and do not suffer the same losses as direct band gap semiconductors. A top metallization and/or ohmic contact layer 732 is deposited directly using suitable metal precursors or elemental source 731. Optionally, optical radiation can be coupled in through the transparent sapphire substrate 720, and thus metal layer 732 may act as a back reflector, thus forming a two-pass optical device or 1+-sun concentrator.

A high defect density at the Si/Al₂O₃ interface may also be treated as a beneficial feature as illumination by solar radiation may enhance the electronic properties, such as the effective doping density due to trapping at defects. That is, defect induced NID may result in advantageous property under 1 or 1+-sun illumination.

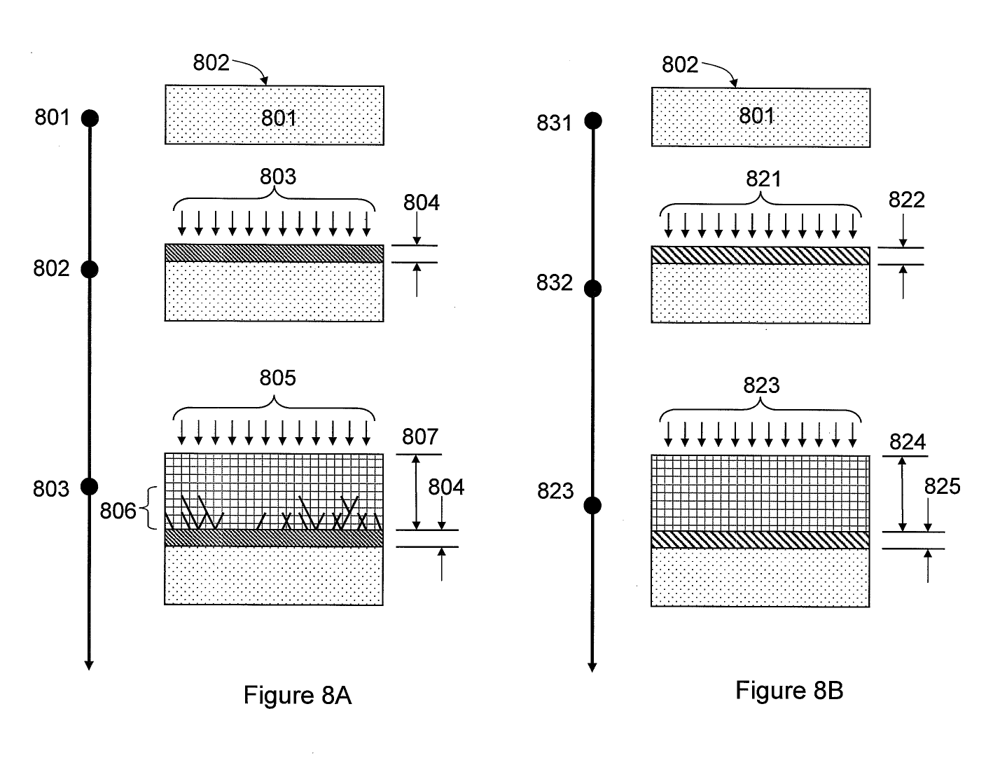

FIGS. 8A & 8B disclose two types of buffer layers that can be used to isolate a semiconductor film from a sapphire substrate. It is well known that aluminum diffuses through thin films of Si and is used in the formation of poly-Si on glass solar cells. An Al layer is deposited upon glass, followed by an amorphous silicon, a-Si, layer. A Si/Al/glass article when thermally treated, induces the Al to migrate and crystallize the a-Si into polycrystalline and/or microcrystalline Si grains. The Al diffuses toward the surface and essentially behaves as a catalyst, resulting in a Al/polySi/glass article. The resulting Si film is typically heavily doped with Al. It is also known that Al diffuses from a sapphire substrate into GaN films deposited at high temperature. It also known that Si epilayer formation suffers deleterious Al contamination from a sapphire substrate when grown at high temperature. Al diffusing into the Si film can be reduced by controlling the growth temperature, growth rate, type of Si precursor and/or providing a thermal gradient to a substrate.

The present invention improves upon prior art methods and solves the issue of Al diffusion from a substrate into a growing epilayer; optionally diffusion of other unwanted materials from a substrate are hindered.

FIG. 8A shows a prepared surface 802 of a single crystal sapphire substrate 801. In step 802, the substrate 801 may be heated in a vacuum to a growth temperature and sources 803 directed at the surface 802 to form an epitaxial buffer layer 804. A buffer layer is chosen from single crystal Al₂O₃ or modification thereof. For example, it is disclosed that nitrogen reduces and/or completely prevents the diffusion of Al species. It is disclosed that nitrogen doping an Al₂O₃ buffer layer (i.e., N:Al₂O₃ ) during growth and/or post growth is beneficial for inhibiting Al migration into a subsequent deposition of semiconductor layers 806 and 807. For the case of low N content, the lattice constant and crystal structure of a buffer layer is similar to that of the substrate. Therefore, Si deposition 805 upon N:Al₂O₃ results in interfacial defects confined in a region 806, due to the mismatch in lattice constants at the interface. However, residual doping of region 806 due to Al impurities is reduced. Alternatively, buffer layer 804 can be deposited such that it is structurally similar to Al₂O₃ but different in chemical composition, for example RE₂O₃.

In yet another embodiment of FIG. 8A is a selective nitridation of surface 802, to form a thin (<100 Å) template layer composed of at least one of: (i) aluminum oxynitride (AlOₓN_{y}); or (ii) aluminum nitride (AlNₓ); or (iii) silicon nitride (SiNₓ); and/or (iv) silicon-aluminum-oxynitride (Si_{z}AlᵥOₓN_{y}) and/or silicon-carbon-nitride (Si_{z}CₓN_{y}) and/or aluminum-carbon-oxynitride (Al_{z}CᵥOₓN_{y}), Al₂O₃ and/or SiOₓ or mixtures thereof wherein 0<x, y, z≦3. Optionally, a template layer 804 is substantially single crystal in structure. A template layer may be uniformly deposited upon the surface 802 or may be spatially patterned to optimize subsequent epitaxy.

FIG. 8B discloses an alternative buffer layer used to fabricate defect-free epi-layer semiconductors. An oriented crystal surface 802 of single crystal sapphire substrate 801 is presented for direct epitaxy of a buffer layer 822. Step 832 uses precursor and/or elemental atomic sources 821 incident upon surface 802 to form buffer layer 822, optionally compliant. Step 823 shows subsequent deposition of semiconductor layer 824 using source 823 for direct epitaxy onto buffer layer 822. The properties of a, optionally, compliant buffer layer are to provide a surface enabling substantially defect free epitaxy of semiconductor layer 824, with acceptably low density of twin and threading dislocations as occurs for process in FIG. 8A. Alternatively, but not limited to, is the use of rare-earth based compounds such as oxides, oxynitrides and others as mentioned in previous patents and applications, for compliant buffer formation. It is disclosed, but not intended to be limited to any particular model, that by controlling the concentration of oxygen vacancies in rare-earth based compliant buffer or barrier layer; said layer can accommodate structural mismatch between a semiconductor layer and a single crystal sapphire substrate surface 802. In one embodiment a rare-earth based barrier layer comprises charged oxygen vacancies, (Oᵥⁿ), of a concentration at least 10¹⁴/cm³ such that migration of alkaline ions and other deleterious species across said barrier layer is functionally impeded.

As used herein, a compliant buffer layer is one that enables a transition from one crystal plane spacing and/or orientation to another, such hexagonal to cubic. Optionally, a substrate surface orientation is chosen from R-plane, C-plane, A-plane, or M-plane, and a compliant buffer layer 825 is chosen from rare-earth-oxynitride compositions 207; optionally other rare-earth compositions, as disclosed in previous patents and applications included herein by reference, may be chosen. A thin film semiconductor layer composition is chosen from silicon and/or germanium and/or carbon and/or mixtures thereof. The composition of the initial buffer layer 822 may be modified during subsequent thermal processing and/or epitaxy of semiconductor layer 824. Therefore, final buffer layer composition 825 may not be equivalent to initial layer 822; modification of layer composition 822 to layer composition 825 may occur through diffusion or by adjusting source components or both.

Alternatively, single crystal silicon layer may be made from a single crystal silicon structure that is bonded to sapphire substrate. It is advantageous to selectively modify the Si epi-layer in the vicinity of the Si/Al₂O₃ interface. These defects may be electrically and optically active and thus impact thin film solar cell designs discussed later. It is desirable for the single crystal semiconductor thin film layer or multilayer structure to be optimized in at least one of the properties, such as, band gap energy, optical absorption co-efficient, long minority lifetime (τᵢ), low concentration of twin defects, threading dislocations, and high carrier mobility. An example process for improving the quality of the silicon layer is known as implantation induced amorphization followed by solid phase epitaxial (SPE) regrowth.

The TEM image of FIGS. 6A and 6B disclose two distinct regions in the structural quality of Si epi-layer on R-plane sapphire substrate 601. Region 607 exhibits a high concentration of twins and other lattice misfit dislocations and/or structural defects during initial epitaxy. Beyond the critical thickness 607, the defects tend to reduce in number and type during further epitaxy, resulting in predominately twin-type defects in region 605. Beyond region 605, a significantly lower number structural defects region occurs shown in region 606, essentially free from structural imperfection. The twins are potentially due to coalescence of the initial islanding of Si clusters upon the native sapphire surface. The clusters grow three-dimensionally until the cluster edges meet laterally thereby forming a twin. Beyond this point the layer effectively grows as a single crystal with defects decreasing with thickness. Increasing the Si layer thickness shows the energy for defect formation is substantially reduced via relaxation of strain and proceeds almost as defect free-silicon. Aluminum induced recrystallization may be occurring.

This evidence can be used to implement selective modifications to the as-grown silicon-on-sapphire structure in order to enhance and/or remove the defective portion 605, shown in FIG. 6.

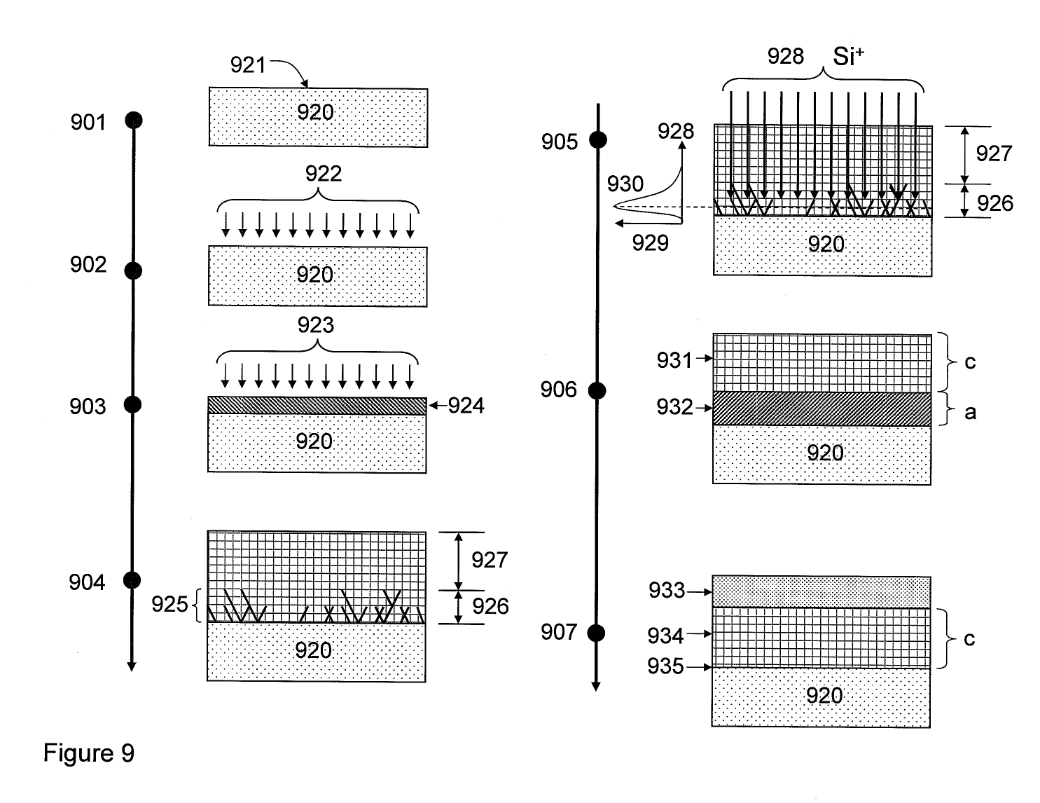

FIG. 9 discloses methods for improving the structural quality of the interfacial defective region. Step 901 shows a clean and well oriented sapphire surface 921. The surface 921 can be treated in step 902 with chemical etch (e.g., H₂ and/or fluorine chemistry such as sulfur hexafluoride SF₆) at high substrate temperature to further smooth the sapphire surface due to scratches from polishing.

It is disclosed in the present invention a step 903 comprising the growth of a epitaxial buffer layer 924 is advantageous for the improvement of subsequent epitaxial growth of thin film semiconductor. For example, a buffer layer can be Al₂O₃, via co-deposition of aluminum and oxygen species 923. Step 904 shows direct epitaxy of a thick semiconductor layer, preferably Si, such that the final portion of layer 927 is relatively free from structural defects compared to the initial region 926 deposited nearest the Si/Al₂O₃ interface. Next, step 905 is a high energy implantation of silicon-ions (Si⁺) 928 localized in a Gaussian profile 930 substantially in region 926. The concentration or dose of Si⁺ is chosen so as to alter the crystal structure of region 926, from defective single crystal type into amorphous Si (a-Si) structure, (i.e., without long range order).

A defect-free semiconductor region 931 is separated from the sapphire substrate 920 by the amorphous semiconductor region 932, as shown in step 906. Thermally annealing the article of step 906 in a suitable oxidizing atmosphere results in solid-phase epitaxy, SPE, of region 932 seeded by the single crystal portion 931. The resultant structure is shown in step 907, where a substantially uniform and defect-free single crystal thin film semiconductor layer 934 is formed free of interfacial defects at the interface 935. For the case of Si on sapphire, the cap layer 933 is composed of SiO₂ and can be used to thin the layer via consumption of Si. Furthermore, oxide and/or insulator layer 933 may function as a tunnel barrier and confining potential for a double barrier single Si quantum well 934, discussed in further detail later.

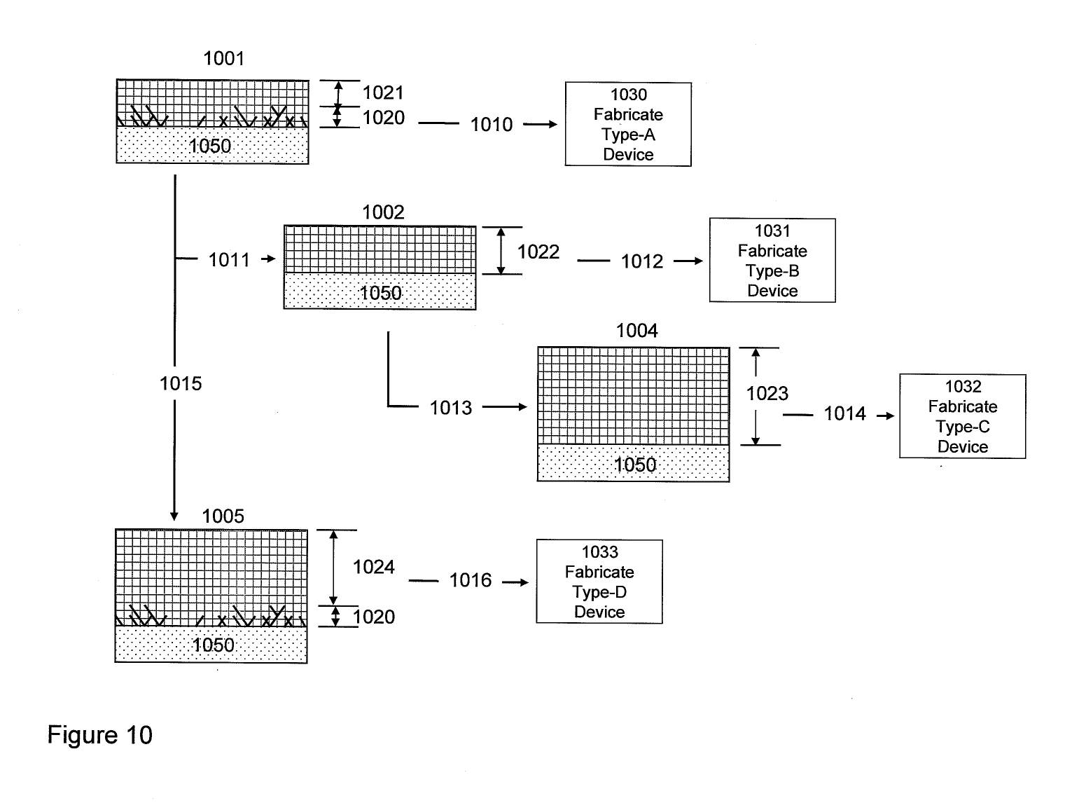

FIG. 10 discloses possible semiconductor-on-sapphire structures that can be used for solar cell fabrication. Thin layer 1001 and thick layer 1005 as-grown semiconductor-on-sapphire structures can be used in solar cell device manufacture as described in the present invention. Thin epitaxial semiconductor layers of the order of 0.1 to 0.5 μm can be used with 1002 and without 1001 semiconductor/sapphire interface modification. The benefit of using the transparent and insulating sapphire substrate for coupling solar radiation into the semiconductor layer(s) is a major functional incentive. For solar cell operation, the device layer 1024 can be relatively thick (0.2-10 μm), compared to the localized defective region 1020. Depending on the device operation, it may be advantageous to remove the defective layer 1021 such that the device layer 1022 is essentially free from defects. In order to form a thick defect free device layer 1023, the defect-free semiconductor 1002 with thin device layer 1022 (processed to remove region 1020) must be thickened via further epitaxial growth of semiconductor to form layer 1023.

Different types of solar cell devices 1030, 1031, 1032 and 1033 can be formed from all the semiconductor-on-sapphire types disclosed in FIG. 10. For example, thin film Si-on-sapphire structure 1001 can be fabricated into solar cell device type A 1030 with active layer formed by region 1021, and p-type Si layer formed by 1020. Type A, B, C & D devices can be chosen from P-N junction, P-I-N, SIS and or MIS structures disclosed herein. An example of Type-C devices fabricated from structure 1004 is via initially forming p-type defect free layer 1023. Next an n-type layer is diffused in from the exposed surface of layer 1023, or a subsequent n-type layer is deposited upon layer 1023, in order to form a p-n junction. The resulting depletion region formed between the p and n sides forms the optically active region.

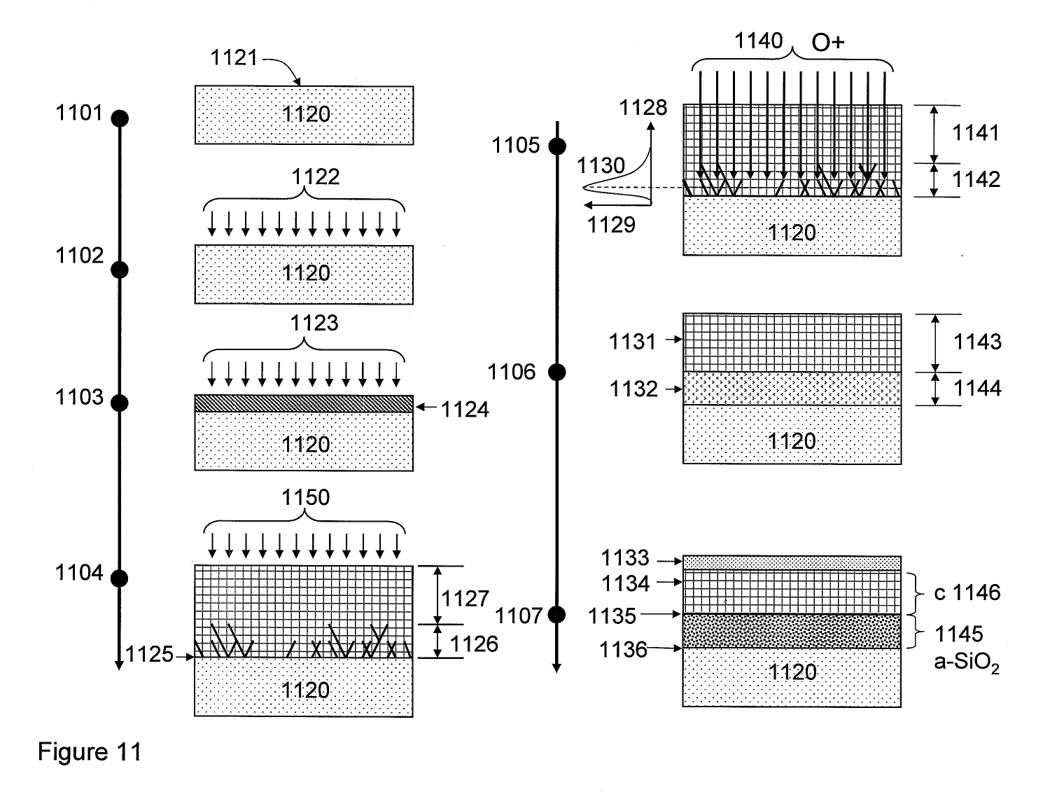

Yet another aspect of the present invention is the removal of the defective portion via oxide formation. FIG. 11 discloses the process steps for selectively converting the defective semiconductor region 1125 into an amorphous and/or insulating and/or transparent layer 1145 in some embodiments. The initial process steps 1201-1204 are similar to the steps outlined in FIG. 9. Step 1105 discloses the selective implantation of oxygen ions (O⁺) 1140 into the defective region 1142. The O⁺ dose is chosen so as form an amorphous layer 1144. Upon thermal annealing in step 1107, the high concentration of oxygen is reacted with the amorphous semiconductor to form a silicate layer, SiOₓ, 1145. Optionally, Si is chosen as the semiconductor 1146 and SiO₂ or SiOₓ is thus formed in layer 1145. An optional oxide layer is formed 1133 on top of the Si active layer 1134. Alternatively, nitrogen may be implanted to form nitrides; alternatively other implant ions are chosen based upon the composition of the semiconductor being used.

A highly defective interface 1125 is transformed into a low defect density interface 1136 after the silicate layer 1145 is formed. Furthermore, the defective Si region 1126 is transformed into an insulating and optically transparent amorphous SiO₂ composition 1145. The Si/SiO₂ interface 1135 is relatively free of interfacial defects. As SiO₂ and Al₂O₃ are both transparent to solar radiation, the resulting structure shown in step 1107 is highly suited to solar cell device operation.

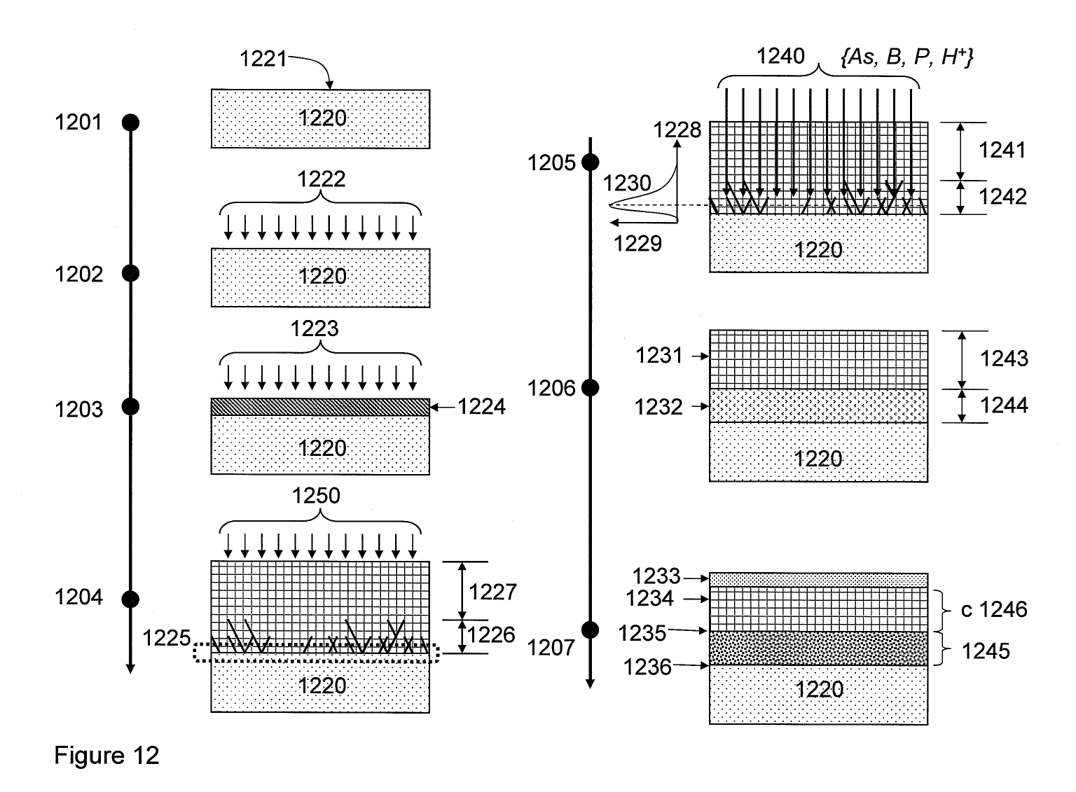

Another example of modifying a defective semiconductor-sapphire interface is via selective doping and/or hydrogen passivation. FIG. 12 shows single crystal sapphire substrate 1220 prepared for epitaxy of semiconductor 1250 forming defective layer 1226 and low defect portion 1227. Step 1205 shows the selective high energy implantation of electrically active impurity atom and/or precursor dopants and/or hydrogen into a region substantially confined to the defective semiconductor region 1242 and/or the semiconductor-sapphire interface. For the case of a Si active layer, the electrical impurity dopants can be chosen from boron (B), Antimony (Sb), arsenic (As), phosphorus (P) and the like. Hydrogen can also be implanted easily to passivate defective region 1242.

Implanted species are localized in region 1244 and are activated via thermal processing to form electrical conductivity type substantially different from region defined by 1246. The conductivity type is chosen either n-type or p-type in region 1245. An optional layer 1233 can be used as an insulating layer or another conductivity type layer.

Methods disclosed for fabrication of single crystal semiconductor-on-sapphire structure can be used for further processing and deposition of more single crystal layers to form complex multilayered structures.

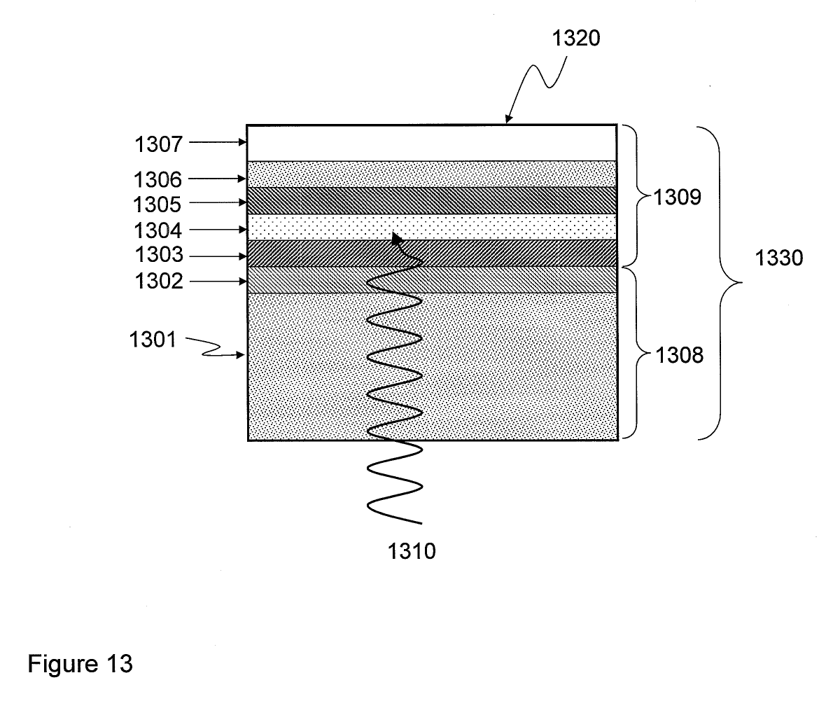

FIG. 13 discloses an exemplary, general multilayer structure 1330 used for manufacture of solar cell device and modules. The sapphire substrate 1301 is highly transparent to solar radiation and can be used to couple light 1310 into semiconductor layers 1309. An optional buffer layer 1302 is included. An example process sequence is first the fabrication of a single crystal semiconductor-on-sapphire structure composed of layers 1301/1302/1303, where the single crystal semiconductor layer 1303 is chosen according to types disclosed in FIG. 10. Further single crystal semiconductor and/or insulator layers are deposited upon the semiconductor layer 1303. For example, a sapphire substrate 1301 with deposited Al₂O₃ buffer or barrier layer 1302 and single crystal p-type Si epi-layer is manufactured. Either in-situ or ex-situ, the following layers are deposited; 1304 intrinsic or NID Si; 1305 n-type Si; 1306 ohmic contact; 1307 high reflector. The structure 1320 can be processed to form a p-i-n solar cell diode disposed upon transparent and insulating substrate. Sequential patterning steps are not shown for clarity.

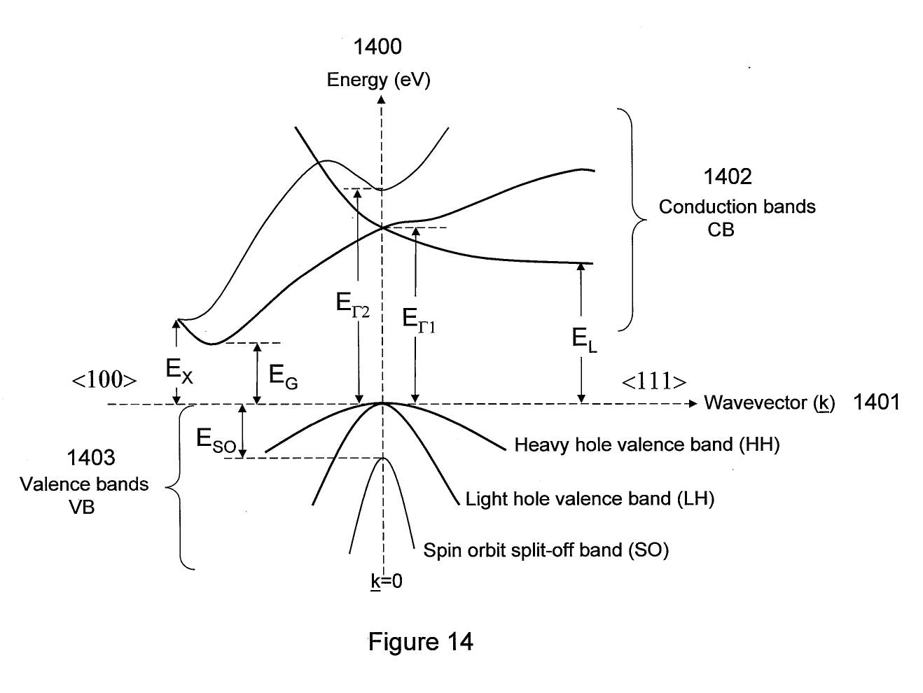

Optionally, but not limited to, is the use of silicon as the active layer for the present invention. Silicon has two regions of interest, namely, the lowest energy indirect band gap E_{g}=1.1 eV and the direct band gap E_{Γ1}=2.5 eV, shown in FIG. 14. Solar photons incident upon Si with energies E_{γ} greater or equal to the fundamental indirect band edge and below the direct band gap, E_{G}≦E_{γ}<E_{γ1}, require the participation of phonons for energy-momentum conservation. The indirect absorption process becomes less efficient and sensitive to temperature due to phonon statistics. The absorption co-efficient for photons in the indirect regime is given by the phonon absorption and emission, such that:

α_{abs}^{indirect}=α_{abs}^{indirect}(phonon absorption)+α_{abs}^{indirect}(phonon emission)=[β.(E_{γ}−E_{G}+E₁₀₆ )²/(exp(E_{Ω}/k_{B}T)−1)]+[β.(E_{γ}−E_{G}−E_{Ω})²/(1−exp(−E_{Ω}/k_{B}T))], (1)

E_{Ω} is the phonon energy, T is temperature, k_{B} is Boltzmann's constant, and β is a constant.

For photon energies above the direct bandgap energy E_{γ}≧E_{Γ1}=2.5 eV, (λ_{Γ1}˜500 nm), light absorption is highly efficient and the absorption coefficient is determined by available conduction band states. For direct transitions the absorption co-efficient varies as:

α_{abs}^{direct}=δ.[E_{γ}−E_{G}(T)]½ (2)

where the temperature dependence of the direct band gap E_{G}(T) is relatively weak in comparison to the temperature dependence of the indirect absorption process due to the phonon statistics.

The total absorption co-efficient is given by the sum

α_{abs}=α_{abs}^{indirect}+α_{abs}^{direct} (3)

and agrees with the experiment as shown in FIG. 1.

Again referring to FIG. 1, it can be seen the direct band gap of Si (E_{Γ1}=2.5 eV) is commensurate with the peak of the solar spectrum. It is disclosed by the present invention the large non-linearity Si absorption co-efficient can be used advantageously in preference to other semiconductor materials for high efficiency solar cell operation.

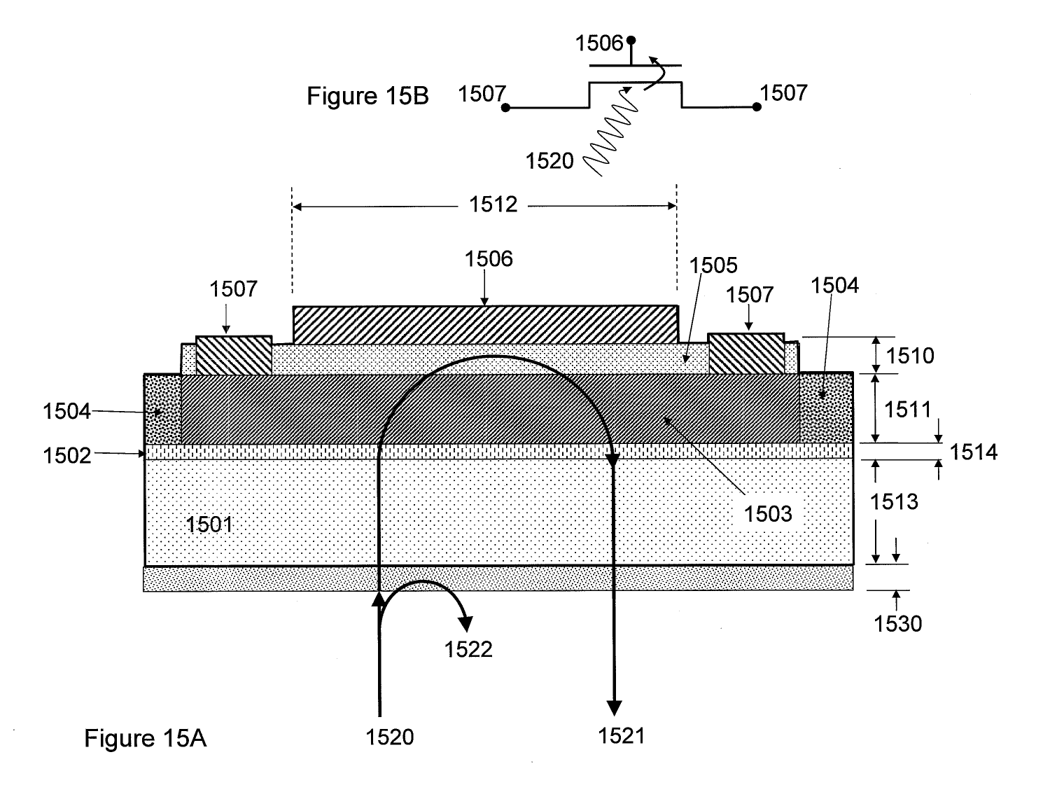

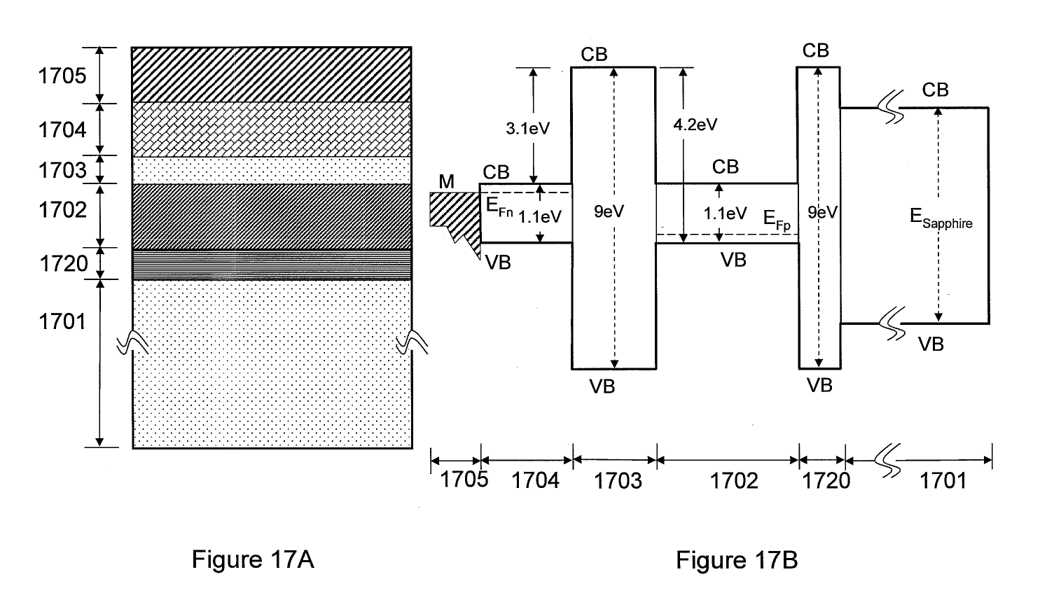

A semiconductor-insulator-semiconductor (SIS) or (MIS) device fabricated upon a sapphire substrate is disclosed in FIGS. 15A and 17B.

By using thin film semiconductor disposed upon transparent substrate, a reflective back surface can be used to cause multiple reflections within the active semiconductor region. This aspect of recycling the unabsorbed incident photons to cause multiple passes enhances the number of photocreated carriers formed for 1-sun incident radiation. For the case of Si active layer and sapphire substrate, incident solar radiation is absorbed differently for high and low energy photons due to highly non-linear absorption characteristics of Si.

In one embodiment a thin film single crystal semiconductor layer 1503 is fabricated upon a transparent substrate 1501 according to the methods of the present invention. Layer 1503 with thickness 1511 is chosen from single crystal Si, and the substrate 1501 with thickness 1513 is chosen from single crystal sapphire. A buffer layer 1502 with thickness 1514 separates the thin film semiconductor 1703 from the sapphire substrate 1501 in order to prevent Al contamination. The thin film single crystal Si-on-sapphire article (SoS) substrate is processed to a MIS or SIS device via optional selective oxidation of thin film Si layer 1503 into SiO₂ or SiOₓ regions 1504 and/or 1505. Layer 1505 is a dielectric and/or insulating material and can be chosen from SiO₂, SiNₓ or single crystal rare-earth compositions as disclosed in patent # U.S. Pat. No. 7,199,015, titled “Rare-earth oxides, nitrides, phosphides and ternary alloys with Silicon”.

An insulating layer 1505 is optionally grown thin to act as a tunnel barrier, alternatively, thick layers can also be used. The metal or conductive contact layer 1506 collects photo-created carriers generated in the active layer 1503 and in a region proximate to the Si/insulator interface. As used herein an “active layer” comprises one or more layers wherein, in at least one of the one or more layers, adsorbed radiation is converted to electron-hole pairs. Electrical contacts to the active layer 1507 complete the circuit. Incident optical radiation 1520 enters the sapphire substrate 1501 and is absorbed in the thin film Si layer 1503. Photons that are not absorbed on first pass through 1503 are reflected by electrode 1506, back through the active layer structure, thereby enabling a second pass 1521 through the active layer 1503. This constitutes an improvement over a 1-sun solar cell device. The MIS SoS equivalent circuit is shown in FIG. 15B. Electrical contacts 1507 are equivalent. Metallization chosen for contacts may be different for the purpose of low ohmic contact 1507 to 1503 and/or specific work function metal for the oxide contact 1506.

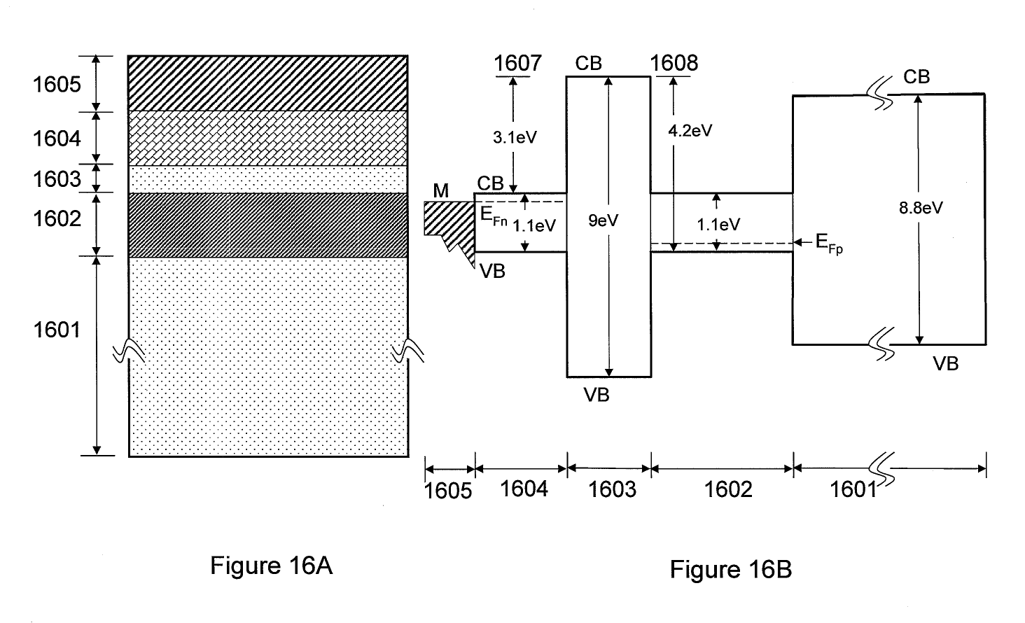

Contact layer 1506 may also be composed of doped poly-Si and metal layer (refer FIGS. 16 & 17). An optional AR coating 1530 can be deposited upon the sapphire substrate 1501 to minimize reflection losses 1522. The AR coating may consist of multiple layers composed of transparent and different refractive index materials.

FIGS. 16A and B and 17A disclose SoS solar cell devices based on SIS structure disposed upon sapphire substrate. FIG. 16A discloses a SIS device structure comprising: single crystal sapphire substrate 1601; single crystal p-type Si active layer 1602; SiO₂ insulating layer 1603; n-type poly-Si contact layer; and metal electrode and/or reflector 1605. Optionally, a buffer layer may be inserted between layers 1601 and 1602 comprising a rare-earth in some embodiments or other compositions previously mentioned.

The energy band structure versus vertical dimension through a multilayer stack is shown in FIG. 16B. Referring to FIG. 2, the energy band gap of SiO₂ and Al₂O₂ are similar and differ mainly in dielectric constant. A single crystal Si layer has equi-partitioned conduction and valence band offset relative to both oxides 1601 and 1603, enabling efficient carrier confinement of photo-generated carriers in Si. Optionally, a SiO₂ layer is formed thin (5-100 Å) to function as a tunnel barrier and thus forming a minority carrier solar cell device.

Large scale manufacture and surface roughness of the underlying sapphire substrate may disadvantage the uniformity of the SiO₂ tunnel barrier. An option is to form the tunnel barrier 1603 from a higher dielectric insulating material chosen from compositions disclosed in FIG. 2. Higher dielectric constant insulators allow equivalent electrical properties to be obtained for a thicker insulator thickness. This alleviates manufacturing tolerances for a tunnel junction.

Solar radiation penetrates with low loss through the sapphire substrate 1601 and is absorbed in the active layer 1602, creating electron-hole pairs. These photo-generated charge carriers can be extracted using the deice designs disclosed herein. For relatively thin active layer thicknesses (<100 nm) 1602, the photo-generated electrons and holes in Si become confined by the large potential barriers 1601 and 1603 and have electronic properties that are subject to quantum size effects. Furthermore, dielectric confinement of the photo-generated e-h pair due to the mismatch in dielectric constants between the semiconductor and insulator layers occurs. Dielectric confinement increases the e-h binding energy and thus provides an opportunity for further tuning the absorption properties of Si.

FIG. 17B shows the electronic band structure of SoS device where an insulating SiO₂ layer 1720 separates the sapphire substrate 1701 from a Si active layer 1702. Similar to the device of FIG. 16, a poly-Si gate 1703 and metal electrode 1705 are shown. FIG. 17B represent an SoS device formed in FIG. 11 via the implantation of oxygen to remove the defect layer during Si epitaxy on sapphire. The electrical and optical properties are anticipated to be similar to the device of FIG. 16A. In all figures, a layer, such as Si active layer 1702 may comprise one or more Si layers, comprising one or more doping levels of one or both carrier types or intrinsic or NID, depending on the device structure desired.

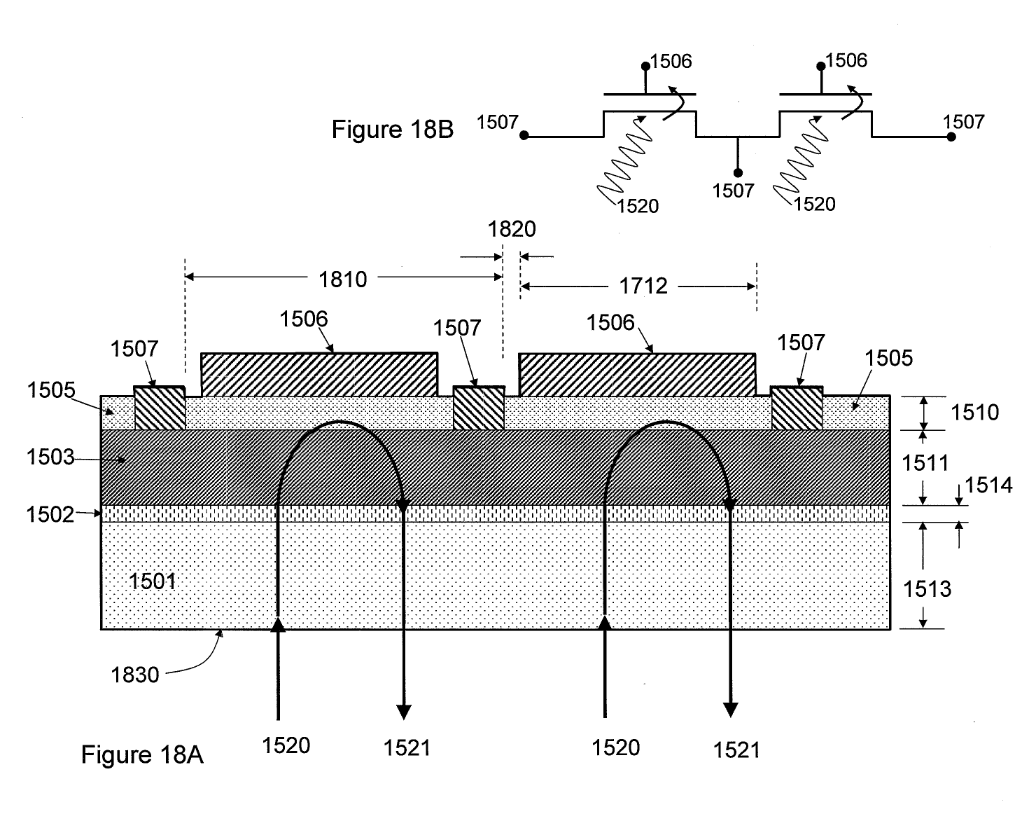

Another optional embodiment of the MIS SoS solar cell device is disclosed in FIGS. 18A and 18B. The devices are fabricated in a similar fashion to the description of FIG. 15A, however, multiple lateral devices are shown interconnected via a common active layer contact 1507. The MIS repeating unit is laterally disposed across the SoS substrate with repeating unit length dimension 1810. The distance between the electrodes 1506 & 1507 is shown as 1820. The electrode dimensions and spacing are chosen to optimize the cell efficiency and is dependent upon the materials used. It is claimed the active layer is continuously optically active and does not suffer dead layers due to opaque electrodes impeding the coupling of optical radiation into the active thin film 1503.

The multiple MIS SoS equivalent circuit is shown in FIG. 18B. Contacts 1507 can be grouped and connected together forming an electrode suitable for the extraction of photocurrent. Similarly, electrodes 1506 can also be connected together, thus forming multiple parallel interconnected MIS SoS devices. That is, grouped contacts 1506 and 1507 form an external two electrical terminal module composed of parallel interconnected MIS devices. Alternately, series connected devices can be fabricated via suitable electrical isolation of the thin film semiconductor.

An advantage of the MIS SoS devices, as fabricated using the method of the present invention, is the use of single crystal Si active layer thin films disposed upon a single crystal sapphire substrate. An MIS device can be optimized for preferentially utilizing the high energy photons of the solar spectrum. An MIS structure is the simplest fabrication method for the formation of solar cell energy conversion devices. The present invention discloses a unique method and device type using single crystal semiconductor MIS structure using SoS substrate.

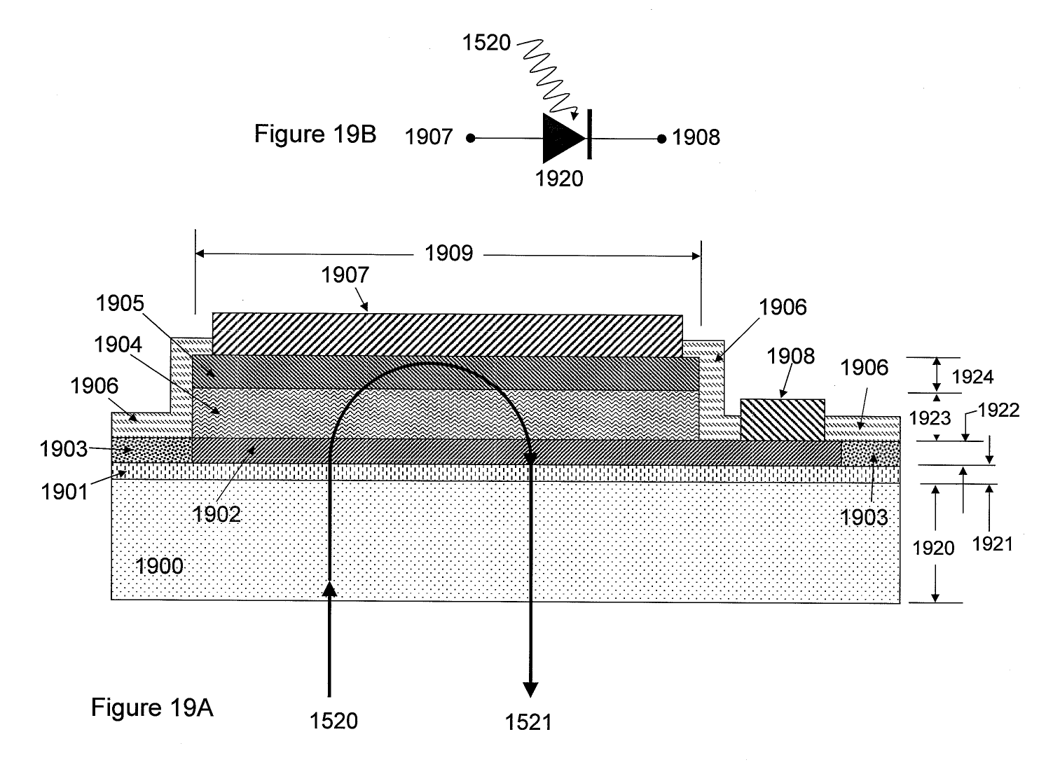

Another optional embodiment of the present invention is the use of multilayer semiconductor structures disposed upon the single crystal semiconductor-on-sapphire substrate. Optional is the use of Si layers chosen from not-intentionally doped (i.e., NID or intrinsic i:Si), n-type (n:Si) and p-type (p:Si) doping. For solar energy conversion devices, layered Si devices of the form of p-n and p-i-n diodes are efficient optoelectronic conversion structures. An example p-i-n SoS embodiment is shown in FIG. 19A. The fabrication of the p-i-n SoS structure is possible using methods disclosed in the present invention. It is understood that p-n junctions and more complex structures are also possible. A sapphire substrate 1900 is separated from single crystal thin film semiconductor 1902 layer via a buffer layer 1901 according to methods disclosed.

A p-i-n layer structure is composed of p-type Si (p:Si) 1902, intrinsic Si (i:Si) layer 1904, and n-type Si ( n:Si) layer 1905. Layers 1904 and/or 1905 can be deposited upon initial SoS article comprising p:Si on sapphire. Lateral oxidation of layer 1902 may be used for lateral electrical isolation of devices disposed across a SoS substrate via regions 1903.

Passivation and/or environmental sealing of the Si epi-layers is via layer 1906 and may consist of SiO₂ and/or SiNₓ. Electrical contacts formed by 1907to the n-type layer 1905 and 1908 to p-type layer 1902 may not be the same composition. For, example, ohmic contacts to the different conductivity type layers may require different metals. Active area useful for photocurrent generation is defined by the i-layer width 1909 of thickness 1923. Optical radiation is coupled in from the sapphire substrate 1520 into the p-i-n device. Contact 1907 forms a reflective surface with 1905 that enables regeneration of photons such that another pass through the i-region may occur. This constitutes a greater than 1-sun concentrator p-i-n solar cell fabricated in a SoS structure. An equivalent circuit is shown in FIG. 19B, and is represented by p-i-n diode 1920.

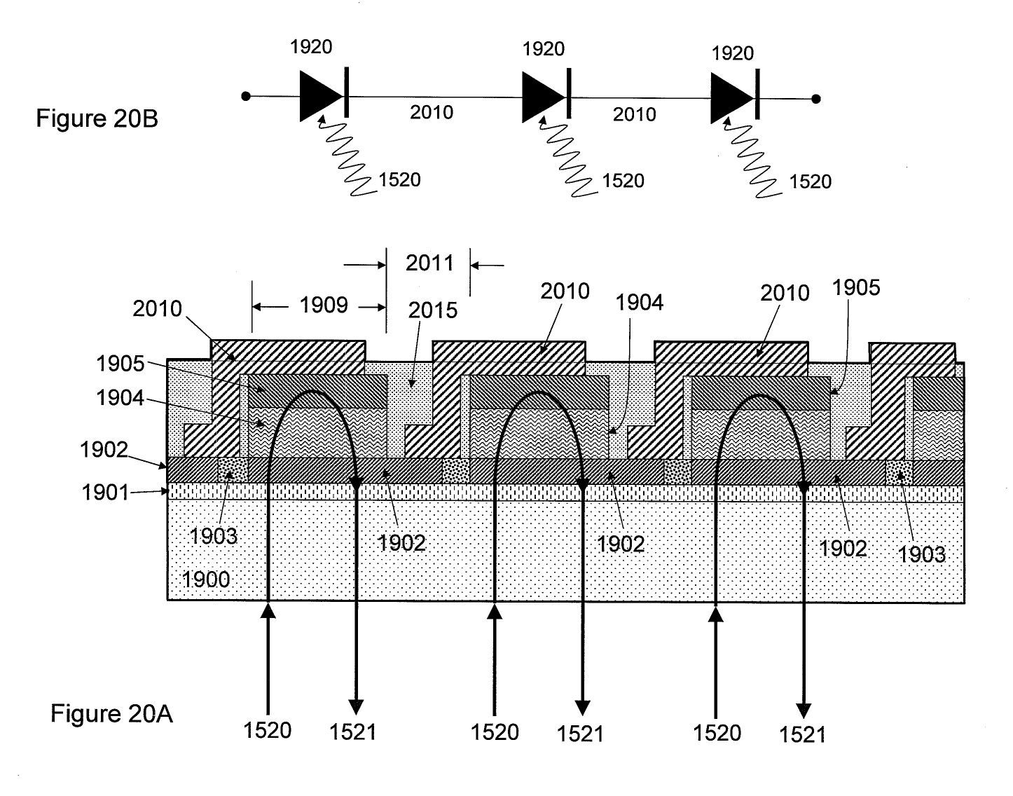

Multiple lateral p-i-n devices can be fabricated across a SoS substrate as shown in FIG. 20A. Utility of a highly resistive sapphire substrate 1900 and/or buffer layer 1901 is the electrical isolation via lateral oxidation and/or etching. Regions 1903 electrically isolate devices formed on layer 1902. The metallization (M) and/or electrical contacts 2010 shows series interconnection of p-i-n device forming the string p-i-n-M-p-i-n-M-p-i-n, etc. Optical radiation incident 1720 upon a sapphire substrate 1900 is coupled through the transparent buffer layer 1901 into i:Si 1904 layers and reflected off contacts 2010, thereby forming greater than 1-sun concentrator structure. Passivation and/or environmental sealing of p-i-n devices is via coating 2015. Equivalent circuit is FIG. 20B where p-i-n devices 1920 are series connected. Photocurrent generated within each device flows through interconnects 2010 thereby forming a two terminal external module.

The absorption co-efficient as a function of wavelength for the thin film semiconductor layer can be used for selecting the thickness and wavelength region of optimum operation. Referring to FIG. 1, it can be seen α_{abs}(λ) in Si varies by almost five orders of magnitude in the range 350≦λ≧1,127 nm. Short wavelength photons are absorbed in a very short distance compared to long wavelength photons in the vicinity of the indirect band gap E_{G}.

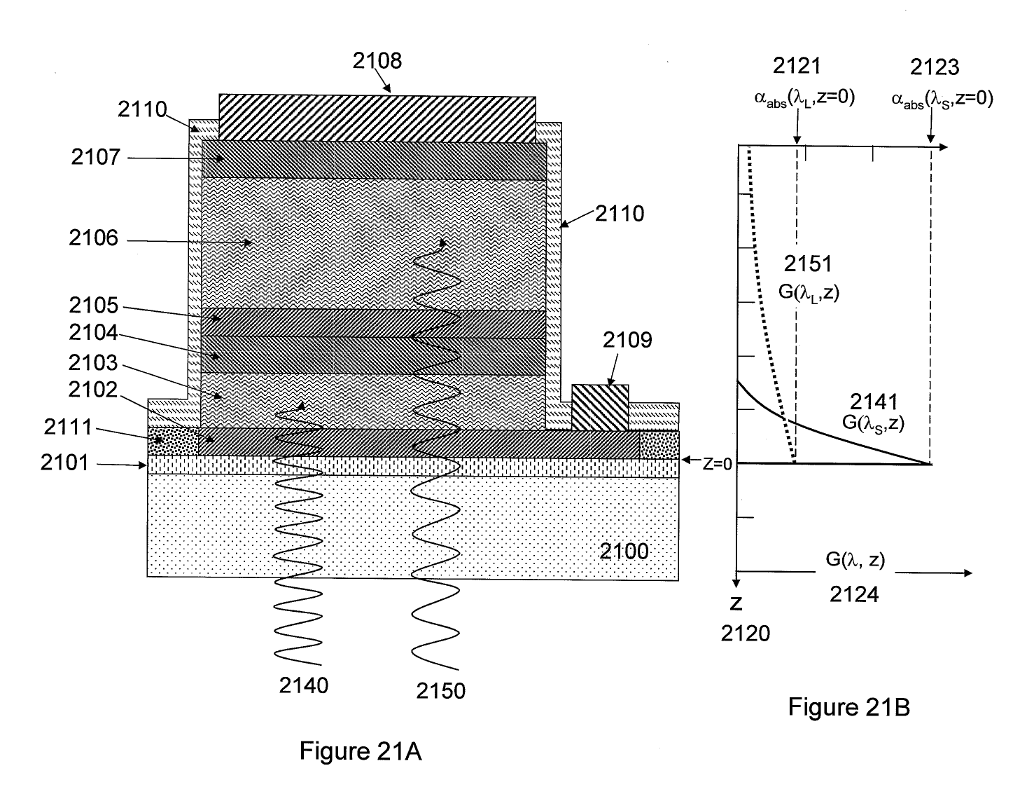

FIG. 21A discloses a stacked layer structure comprising two p-i-n diodes comprising different intrinsic absorber thicknesses. Optionally, a semiconductor is selected from single crystal Si and the substrate from single crystal sapphire 2100. An example embodiment discloses a first p-i-n diode comprising p:Si layer 2102, i:Si layer 2103 and n:Si layer 2104. A second p-i-n diode is formed upon a first diode comprising p:Si layer 2105, i:Si layer 2106, and n:Si layer 2107. This sequence forms a p-i-n-p-i-n stacked diode. Alternately, the sequence n-i-p-n-i-p can also be formed. Yet another optional embodiment uses a layer sequences p-i-n-i-p or n-i-p-i-n. It is understood that i:Si and NID Si are substantially and functionally identical

Regardless, NID and/or i-regions are grown with different thickness, L_{S} 2204 and L_{L} 2203, such that a thinner region is positioned closest to the sapphire substrate. Electrical contact layers 2109 and 2108 are formed on the first and last layers comprising stacked diodes. Incident short wavelength optical radiation λ_{S} 2140 enters a transparent substrate 2100 and is preferentially absorbed in first thin i;Si layer 2103 and/or p-i-n diode. Similarly, long wavelength optical radiation λ_{L} 2150 enters a transparent substrate 2100 and is preferentially absorbed in a second thick i:Si layer 2106 and/or p-i-n diode.

FIG. 21B shows a generation rate G(λ, z)=α(λ)F(1−R)e^{-(α(λ).z)} 2124 of electron-hole pairs as a function of vertical distance, z 2120, through a layered structure. F is the incident photon flux and R is the reflectivity of light at the surface, and α(λ) is the wavelength dependent absorption co-efficient and z is the distance through the structure. Short wavelengths in Si exhibit very large absorption co-efficient (α(λ_{S})=100 μm⁻¹@λₛ=400 nm) and thus a first i:Si region 2103 can be made thin (L_{L}˜0.01 μm), optionally less than about 20 nm. The generation rate of e-h pairs for short (λ_{S}) and long (λ_{L}) wavelengths as a function of propagation through a structure is shown as G(λ_{S},z) 2141 and G(λ_{L},Z) 2151, respectively. Similarly, long wavelength photons co-incident with a band edge E_{G} exhibit relatively low absorption co-efficient and thus a second i-region 2106 can be made thick (α(λ_{L})=0.01 μm⁻¹@λ_{S}=1000 nm, L_{L}˜100 μm), optionally greater than about 100 nm.

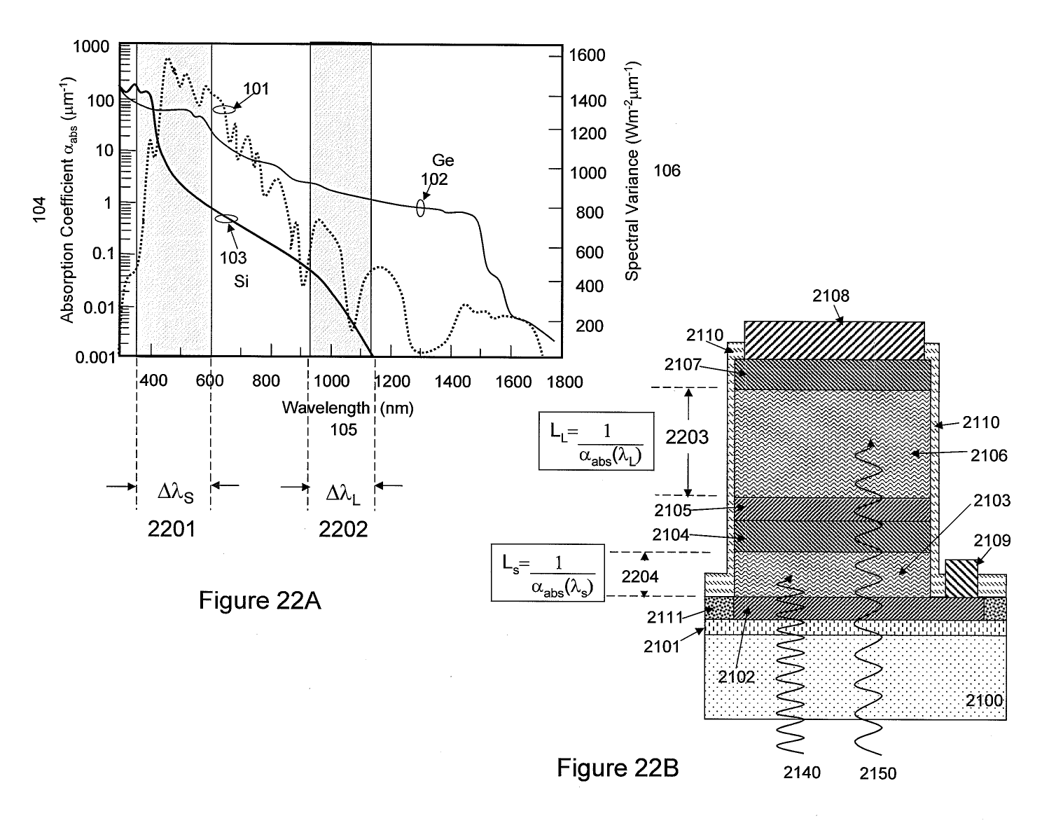

FIGS. 22A and 22B further show optional wavelength bands 2201 & 2202 used for an example tandem Si p-i-n-p-i-n solar cells, with intrinsic regions formed with thicknesses L_{S} and L_{L}. The theoretical efficiency of the proposed tandem cell is equivalent to a two-junction solar cell, and thus is capable of efficiency in excess of the SJ limit <29%. It is important to note that in some embodiments disclosed a two-junction device uses only Si semiconductor materials in the layer stack. This technique works particularly well for Si compared to Ge due to the large non-linearlity in absorption co-efficient of Si as a function of wavelength and advantageous overlap with the solar spectrum.

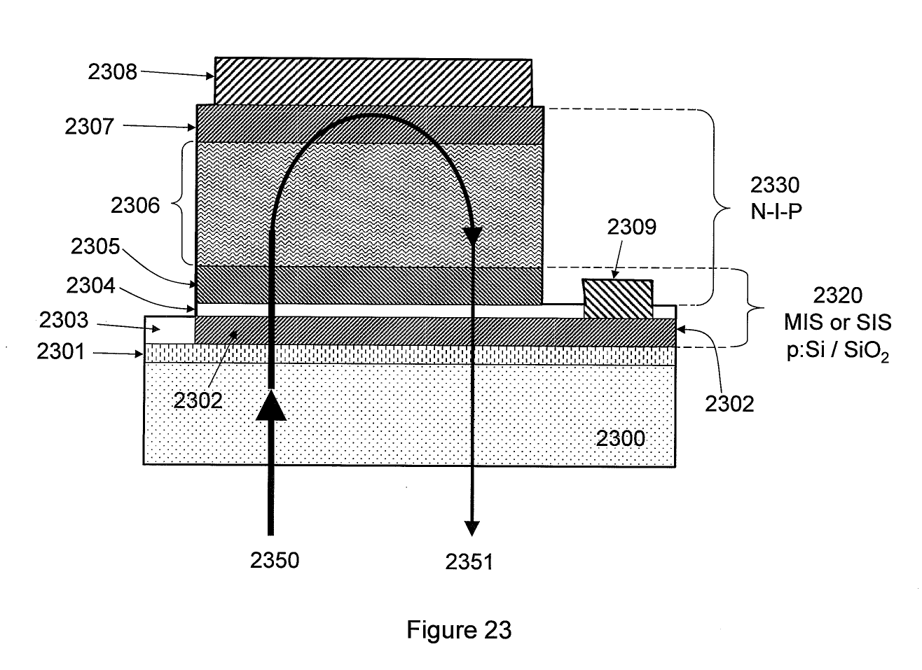

Another optional embodiment utilizes a hybrid device based on incorporating the advantageous features of MIS and PIN solar cell devices. FIG. 23 discloses a MIS/PIN hybrid wherein the MIS section 2320 is used as the short wavelength converter and the PIN device 2330 is used as the longer wavelength converter. Optionally, semiconductors forming stacked layers are single crystal and/or polycrystalline and/or amorphous structure. Insulator layer 2304 may be chosen from amorphous SiO₂ and/or single crystal rare-earth based materials, such as rare-earth oxide and oxynitride (REOₓ or REOₓN_{y}) or others mentioned herein. If insulator 2304 is amorphous then thin film semiconductor layers 2305-2307 may be chosen from polycrystalline and/or amorphous structures. Alternately, if insulator 2304 is chosen from substantially single crystal compositions (e.g. rare-earth oxides or others mentioned previously or subsequently), then epitaxial Si or Ge or a mixture may be deposited directly upon 2304, thereby forming a single crystal epitaxial growth sequence according to a method disclosed in the present invention.

Referring to FIG. 23, an example embodiment of the MIS/PIN hybrid is via the following layer sequence, comprising: single crystal R-plane sapphire substrate 2300; buffer layer 2301; a first semiconductor layer p:Si 2302; a insulator layer 2304; a n:Si layer 2305; a NID i:Si layer 2306; and a p:Si layer 2307. Electrodes 2308 and 2309 may be metallization to contact semiconductor layers 2307 and 2302, respectively. In some embodiments, a layer sequence forms a MIS diode 2320 with silicon contact layer 2305 to the insulator 2304. The example in FIG. 23 is a p:Si/SiO₂/n:Si stack (i.e. layers 2302/2304/2305) forming an inversion channel MIS structure suitable for high energy photon solar energy conversion. The following N-I-P diode 2330 (n:Si/ i:Si/ p:Si) structure is formed via the layer sequence 2305/2306/2307. An intrinsic layer 2306 thickness is chosen to advantageously absorb a portion of the solar spectrum that has not been depleted by the MIS device. Solar optical radiation 2350 is incident upon a sapphire substrate 2300 and is coupled into a MIS/PIN hybrid via an optional transparent buffer layer 2301.

An MIS device is optionally made with a thin insulator 2304 (5≦L_{OX}≦500 Å) so as to allow tunneling of photo-created carriers in the active layer 2302. Referring to FIG. 16B, UV generated hot electron injection from the CB, conduction band, and/or VB, valence band, of Si into the CB of the insulator may also occur. Electrode 2308 can also be engineered, optionally, to function as a back reflector allowing long wavelength radiation not absorbed by the MIS section to be recycled back through the device. Radiation 2351 is indicative of radiation reflected from interface 2307/2308 and passing back trough active areas 2330 and 2320, thus improving the efficiency above 1-sun incidence. Therefore, a MIS/PIN hybrid solar cell fabricated on SoS also forms a two-junction and greater than 1-sun solar concentrating device.

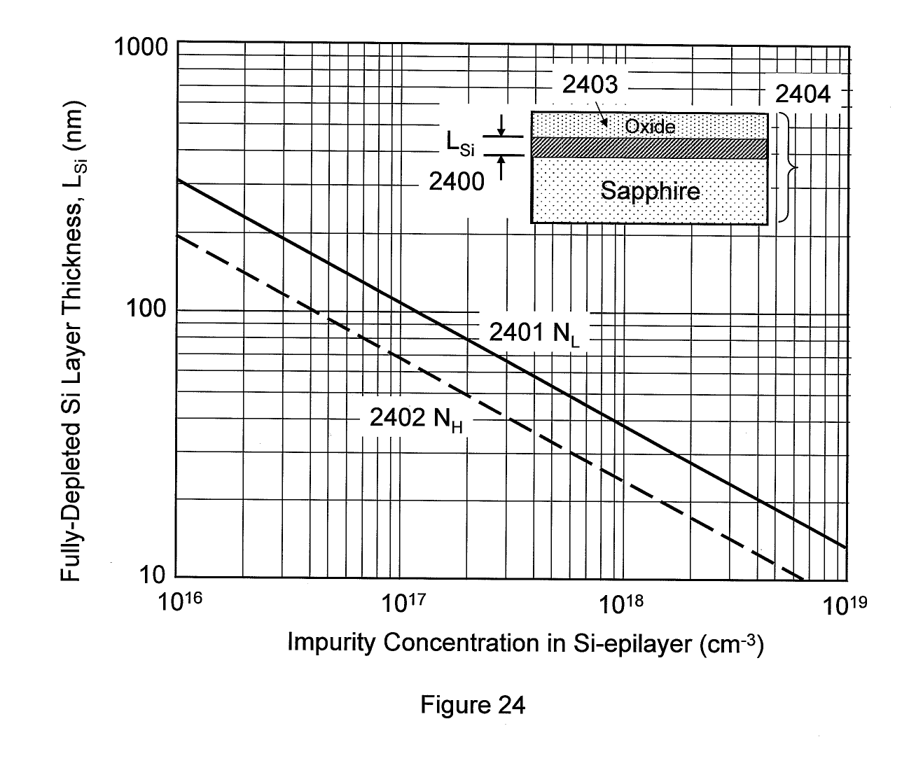

Fully-depleted, FD, thin film Si epi-layers on sapphire substrates allow new types of solar cells to be fabricated. An advantage of using fully-depleted Si-on-sapphire (FD-SoS) structures for MIS and/or SIS solar cell devices as disclosed herein is the ability to form an inversion layer with thickness equal to the total thin film Si layer. That is, not just beneath the thin oxide (i.e., Si/SiO₂ interface) as occurs in bulk semiconductor MIS and/or thick Si film SoS. Referring to FIG. 24, a solar cell SoS active layer 2400 is classed as partially depleted (PD) if the semiconductor layer 2400 is thicker than the depth of the depletion region. Solar cell active layer 2400 is classified as fully depleted (FD) if the semiconductor surface layer is equal to the depth of the depletion region. A solar cell active layer will be partially depleted or fully depleted depending on the active layer thickness above the sapphire substrate and the effective doping concentration in the channel, taking into account the number and type of grain boundaries, twins and electrically active defects. To form a FD-SoS solar cell, the effective semiconductor doping concentration must be low enough that the depletion region extends throughout the entire thickness of the active layer. FD-SoS solar cells enable the engineering of new types of solar cells.

The depletion depth δ_{Si} of a Si epi-layer disposed upon an insulating and/or sapphire substrate is given by:

δ_{Si}=[2k_{B}Tε_{Si}/(q²Nᵢ)]^{1/2} (4)

where ε_{Si} is the permittivity of Si, q=electron charge, Nᵢ=the impurity donor/acceptor charge concentration.

FIG. 24 discloses the trend in epitaxial semiconductor layer thickness L_{Si} 2400 required to form FD-SoS 2404 as a function of the effective impurity concentration. Curves 2401 and 2402 represent the trend for small and large impurity concentration in layer 2400.

For the case of ideal single crystal silicon-on-sapphire (SoS) structure, with low defect density and negligible twin defects at the Si/Al₂O₃ interface, the Si layer thickness required to achieve full depletion depends on the impurity concentration N_{L} 2401. For example, if Al contamination from the sapphire into the Si is low, a NID impurity concentration <10¹⁶ cm⁻³ is possible, and thus L_{Si}=300 nm is the maximum thickness for NID FD-SoS. As the intentional doping is increased, for example when p:Si is desired, then the thickness required for full depletion decreases rapidly. If there are a large number of electrically active defects within the semiconductor layer 2400, then the L_{Si} versus impurity concentration follows the curve shown as 2402.

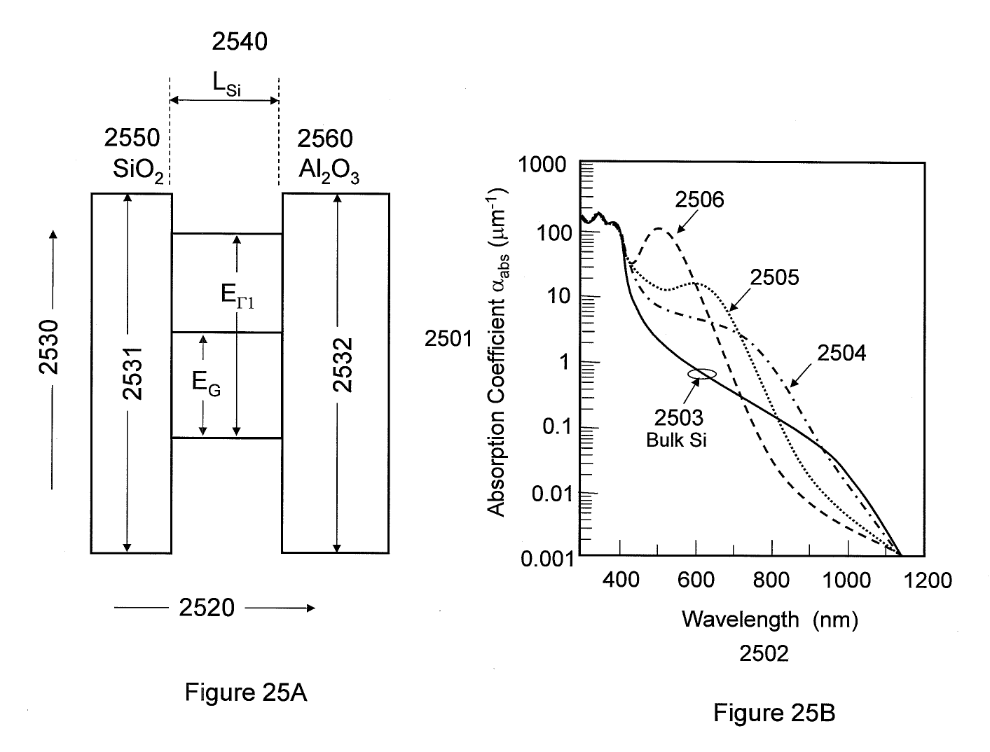

Another example embodiment is the construction of quantum confined and/or dielectrically confined thin film semiconductor layer disposed upon single crystal sapphire substrate. FIGS. 25A and 25B disclose the optical tunability of the Si absorption spectrum by the choice of the Si layer thickness L_{Si} 2540 sandwiched by dielectric insulating layers 2550 and 2560.

FIG. 25A shows schematically the energy band structure 2530 versus distance 2520 through an example SiO₂/Si/Al₂O₃ heterostructure. The Si layer forms a potential well sandwiched between large band gap, about ≧2 eV energy insulators and/or electronic barriers. Rare-earth compounds are suitable replacements for SiO₂ and Al₂O₃, e.g. [RE material]/Si/[RE material]. Si has two band gaps of interest, the indirect E_{G} and direct E_{γ1}. FIG. 25B shows the absorption co-efficient 2501 versus wavelength 2502 of the heterostructure as a function of L_{Si} 2540. The bulk Si optical absorption co-efficient 2503 suffers low strength at long wavelengths in the vicinity of the indirect band gap, and increases rapidly approaching the direct band gap energy toward 400 nm. By reducing L_{Si} into the quantum confinement regime (L_{Si}<500 Å) quantization of electronic states occurs in the Si potential energy well. Electron-hole pairs generated via absorption of solar radiation can be tuned via appropriate design of the quantum well thickness. Alternatively, the dielectric constant mismatch between the barriers and the Si well can also produce dielectric confinement of photo-generated charges in the Si layer. For example, photo-generated electron-holes pairs can have an increased binding energy due to dielectric confinement. Therefore, it is disclosed electronic confinement and/or dielectric confinement can be used to increase the absorption co-efficient advantageously for higher efficiency solar cells. Schematically, curves 2504, 2505 and 2506 predict the tuning of an absorption resonance in the Si layer via reducing the L_{Si} from 100 nm (2504), to 50 nm (2505) and 10 nm (2506). At approximately L_{Si}=10 nm, the absorption co-efficient is enhanced at ˜2.5 eV. The energy quantization and/or dielectric confinement of the photo-generated electron-hole pair can be engineered to resonate with peak of the solar spectrum or with direct band gap energy by appropriate construct of the Si well width and dielectric cladding compositions.

Yet another example embodiment is the use of high dielectric constant layer 2550 chosen from the materials shown in FIG. 2. The FD-SoS and quantum or dielectric confined SoS structures are applicable for high efficiency MIS or SIS solar cell devices disclosed herein.

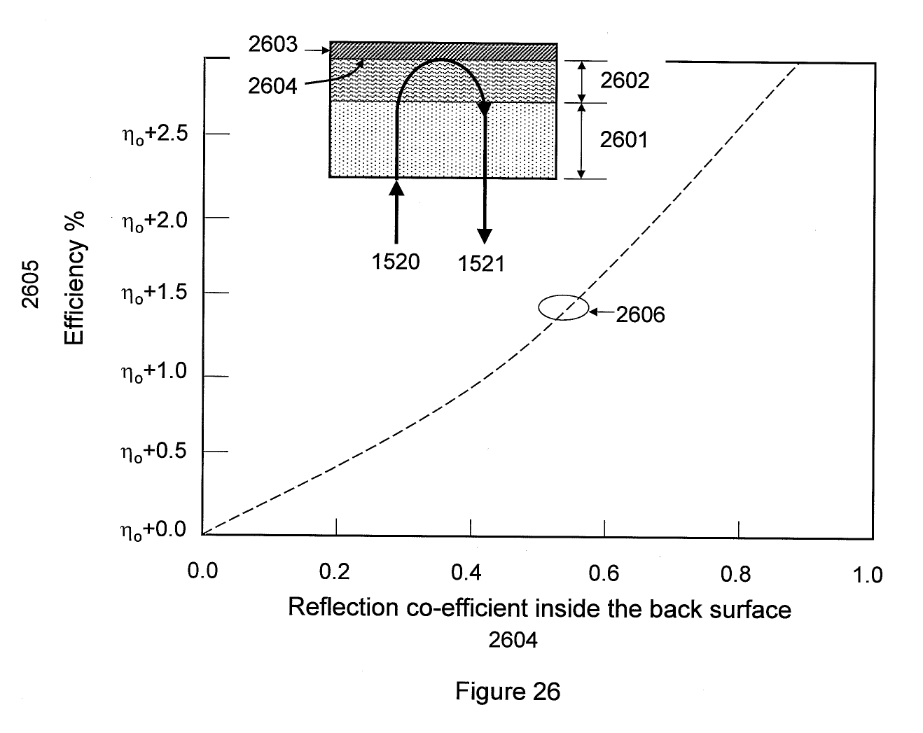

The influence of a rear reflector and/or electrode in the 1+-sun devices disclosed herein can be used to increase the solar cell efficiency significantly. FIG. 26 discloses schematic influence on efficiency 2605 due to reflection co-efficient of rear surface 2604, for a double pass solar cell. Incident solar radiation 1520 enters the cell and is reflected from the back surface reflector and/or electrode 2603. The reflected ray 1521 substantially reflects or is specularly reflected and is recycled by passing again through the active region 2602 and sapphire substrate 2601.

It is understood that many such internal reflections may also occur. The refractive index of Si is highly non-linear for optical energies above the fundamental band gap. Approaching the direct band gap the refractive index resonates and peaks at a value of n_{Si} (λ=350 nm)˜6.7, almost doubling from the indirect band edge value of n_{Si} (λ=1120 nm)˜3.5. The curve 2606 shows the general dependence for efficiency versus various values of reflection coefficient 2604, where ηₒ is the cell 1-sun efficiency. The value ηₒ+0 represents an ideal case of zero reflection for a highly absorbing region 2603, but otherwise doe not contribute to the cell photocurrent. Clearly, as the reflectivity of the rear surface 2604 increases, the efficiency 2605 increases.

It is disclosed that efficiency increases between 1-5% above a nominal efficiency ηₒ, are possible using the 1+-sun concentrator approach disclosed herein. The layer dimensions of the active absorber region 2602 and transparent sapphire substrate 2601 as well as the reflection loss at the sapphire-air interface can be varied advantageously as further parameters.

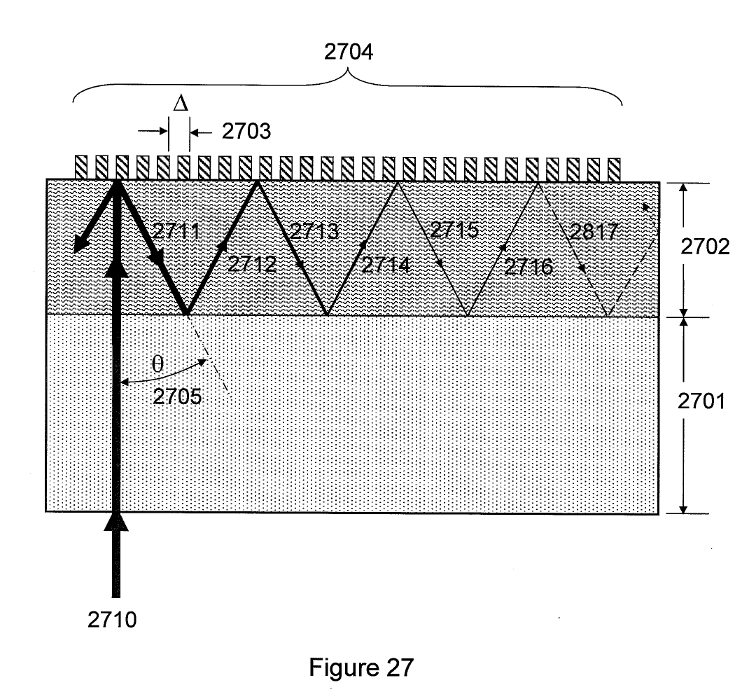

Wavelength dependent reflection is possible using a rear contact patterned to function as a diffraction grating. FIG. 27 discloses the use of a diffractive grating and/or element 2704 positioned at the rear portion of the semiconductor layer 2702. The semiconductor active layer 2702 is disposed upon a transparent substrate 2701, and near normal incident broad band solar radiation 2710 is incident upon the substrate 2701. It is understood that other angles of incidence are also possible producing similar dispersive effective within the active layer.

In one embodiment, the substrate 2701 is chosen from single crystal sapphire and the semiconductor active layer 2702 is chosen from substantially single crystal silicon. The incident optical radiation 2710 enters absorptive layer 2702 and the unabsorbed portion is reflected from diffractive element 2704. The zero order diffraction beam is retro-reflected for normal incidence constituting a double pass through 2702 (i.e., 1+-sun equivalent). The principle diffracted order portion 2711, may be chosen to be the 1^{st}, 2^{nd}, or more order from the grating. Owing to the large refractive index contrast between the Si and Al₂O₃, the total internal reflection of subsequent beams occurs, i.e., beams 2712, 2713, 2714 and so on. As the internally reflected beam propagates in a direction parallel to the Si/Al₂O₃ interface, the absorptive material depletes the beam and converts the photons into photo-generated charge carriers. The broad band solar spectrum incident optical radiation 2710, selectively reflects specific wavelengths from the diffractive element at a unique angle θ(λ) 2705, dependent upon the periodic grating spacing Δ 2703, defining the periodic refractive index modulation of diffractive element 2704 disposed upon the surface of the semiconductor layer 2702. Only prominent diffracted order 2711 is shown, although others will also occur.

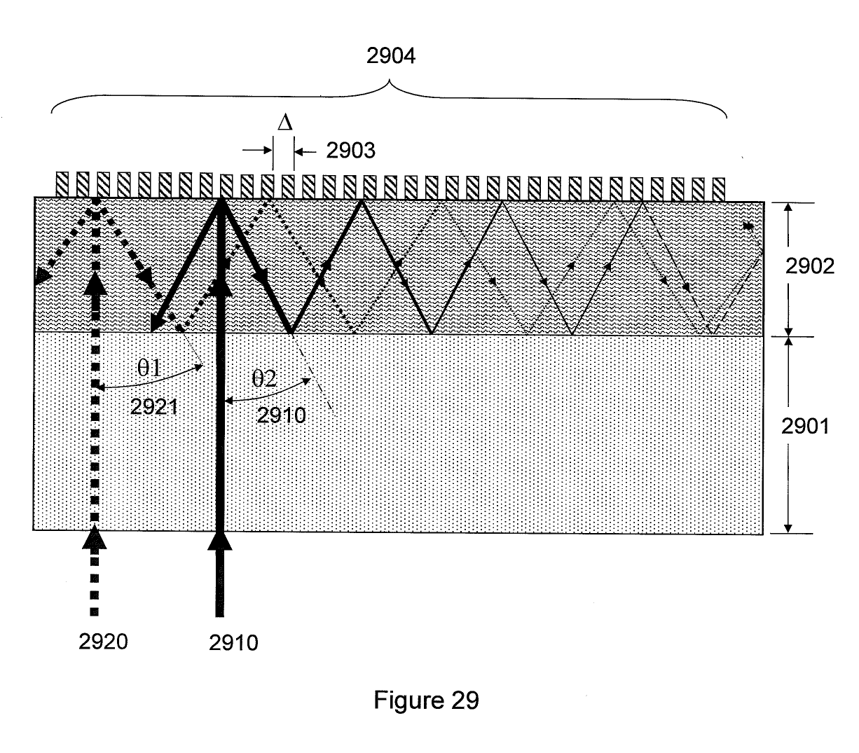

FIG. 29 shows the effect of two different wavelengths λ being separated from broad band solar radiation 2920 and 2910 by diffractive element 2704. The relationship Δsinθ=mλ, where Δ is the grating period 2903, m is the diffraction beam order (m=1, 2, 3 . . . ) allows longer wavelengths to be diffracted at larger angles θ. Wavelength dependent total internal reflection at the Si/Al₂O₃ interface occurs at the critical angle θ_{c}(λ)=arcsin(n₂(λ)/n₁(λ)), where n₂(λ) is the refractive index of the less dense medium, and n₁(λ) is the refractive index of the denser medium. For example, n₂ (λ) 32 n_{Si}(λ) and n₁(λ)=n_{Sapphire}(λ).

An advantage of the optical structure schematically described in FIG. 29 is the planar separation of wavelengths in the layer 2902. This can be used for selectively creating charge carriers within spatially confined regions within the active layer 2902, thereby substantially extracting the said charge carriers created by different wavelengths dependent upon the absorption length within the absorbing waveguide. That is, a dispersive and absorptive waveguide can be designed to operate in multi-mode operation, and thus advantageously recycle a large band of wavelengths within the plane of active layer.

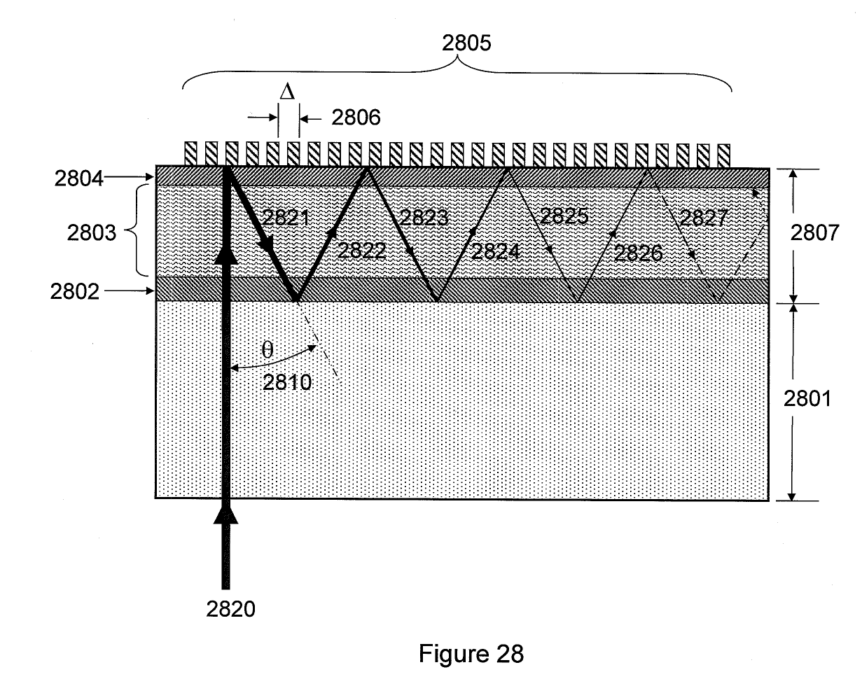

Therefore, in one embodiment, optical guiding structures suitable for solar cell operation are configured to operate in multi-mode operation, and thus support a large number of wavelengths. FIG. 28 further discloses the diffractive effect incorporated into a p-i-n solar cell 2807 disposed upon a sapphire substrate 2801. It is understood the same effect is possible in a p-n junction.

Incident solar radiation 2820 enters intrinsic NID absorber region 2803 and is reflected and/or diffracted from the patterned electrode 2805. In preference, layer 2804 is n-type Si, 2803 is i:Si or NID:Si and 2802 is p-type Si. Diffractive element 2805 has periodic metallizations of lateral spacing A. An advantage of the P-I-N solar cell device disclosed in FIG. 28 is that long optical propagation lengths along a direction parallel to the Si/Al₂O₃ interface can be achieved in very thin Si films. The photo-generated carriers, however, need only transit the i-region in a vertical direction before being collected at the p- and n-type regions. Therefore, a device of FIG. 28 construct is capable of producing high efficiency solar cell operation using thin Si films disposed upon sapphire substrate. The instant invention solves a long standing problem of optimizing long optical interaction length and efficient photo-generated carrier collection.

Solar radiation 2820 is efficiently optically confined within an active semiconductor layer 2803 by means of cladding layer 2804 providing a large refractive index mismatch. The grating coupler and/or dispersive element and/or upper optical cladding layer also functions to confine the radiation in a vector substantially parallel to the plane of the layers. Therefore, large semiconductor interaction lengths can be provided without the need for very thick semiconductor layers. Conversely, photo-generated charges are created in the thin semiconductor layer and are separated and efficiently collected by built in electric field generated by the p-i-n diode structure. Using a thin p-i-n structure therefore requires lower minority carrier lifetime semiconductor and thus can aid in the cost-effective manufacture of the solar cell on sapphire device.

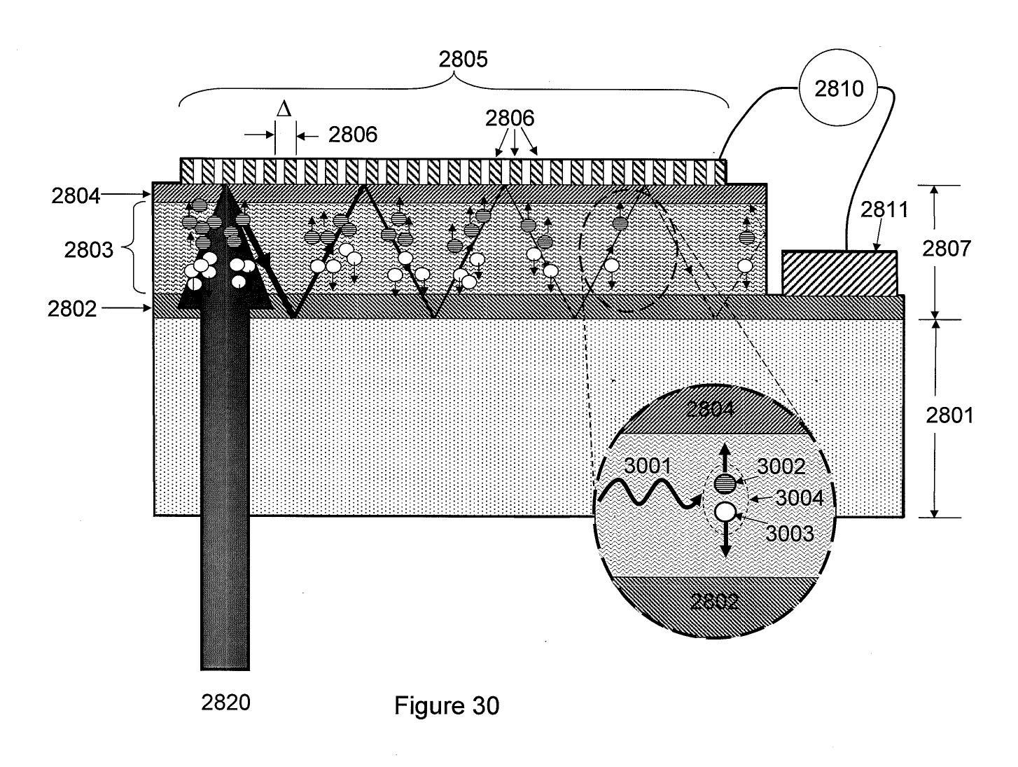

FIG. 30 shows the broad band solar radiation 2820 incident upon a device. Diffractive element 2805 separates preferentially the high energy portion of the solar radiation 2820. Wavelengths suitable for total internal reflection propagate in a direction parallel to the plane of the layers generating charge carriers via creation of electrons and holes. The charge carriers separate due to the built in electric field generated by the p-i-n structure, and are collected at the p-type and n-type contact regions. The photocurrent is extracted into an external circuit 2810. The diffractive element 2805 is shown as a periodic metal electrode with spacing 2806. The individual electrodes may be fingers separated by air or low refractive index material. The fingers 2806 are electrically connected forming a singular electrical contact. A separate contact 2811 forms ohmic electrical connection to layer 2802.

The inset of FIG. 30 depicts the absorption of a photon 3001 and the creation of an electron (3002) and hole (3003) pair. The electron and hole are created simultaneously 3004 and separate to opposite side of the intrinsic depletion region 2803. A similar diffractive contact is also possible for the MIS and SIS structures described herein.

It is disclosed that complex diffractive elements, such as chirped period gratings, 1-D or 2-D photonic band gap gratings, and volume holograms as well as others are also applicable to the present invention. It is disclosed that the use of multilayer refractive index dispersion elements are also possible for use as the rear reflector.

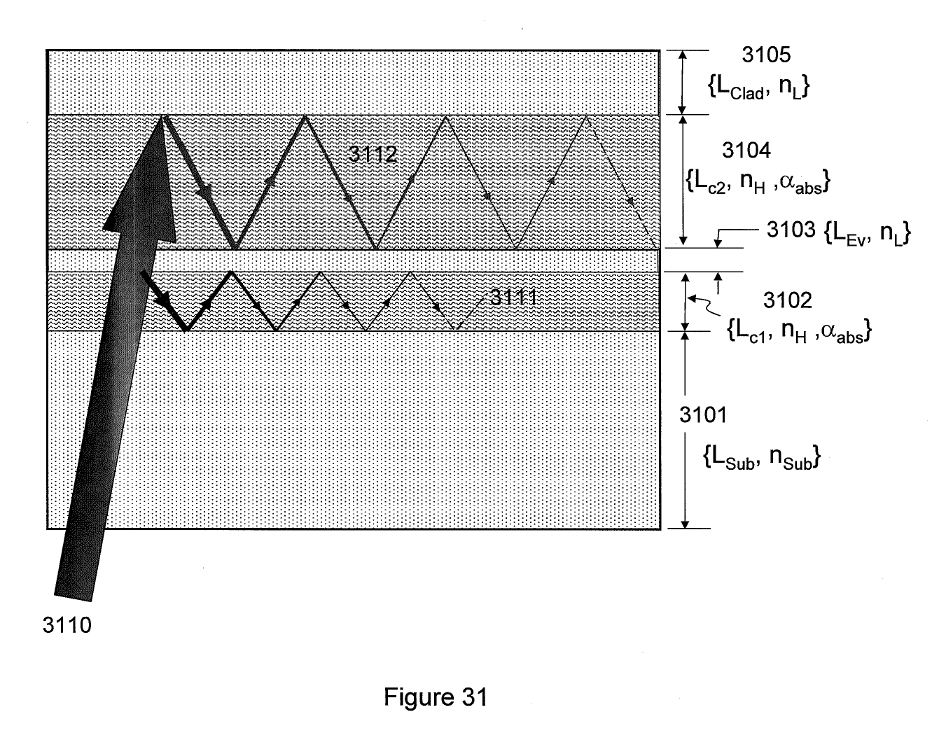

FIG. 31 discloses the use of multilayer guided wave structures for selectively dispersing and guiding of different wavelengths and/or band of wavelengths within spatially separated layers. It is an aspect of the present invention to confine the dispersed wavelengths from the incident solar radiation into a flux substantially in a direction parallel to the plane of the layers, thus enabling long optical interaction lengths in relatively thin semiconductor layers. The cladding and core layers serving to confine the guided modes are shown with an evanescent wave coupler 3103 between active semiconductor layers 3102 and 3104.

An optical device structure is only shown for clarity, and it is understood that an opto-electronic function is superimposed upon a basic device shown. Broad band solar radiation 3110 is incident upon an optical structure as shown. Fresnel reflection losses from an initial sapphire interface is not shown, but anticipated to require optimization. By way of example and not limited to the physical structure shown, an optical structure consists of a transparent substrate of thickness L_{sub} and low refractive index n_{sub} and low absorption material 3101. An active absorptive semiconductor layer 3102 is used for some optoelectronic function. The guided wave selectively propagating in wavelength mode 3111, shown to be depleted in number of photons as it propagates in absorptive medium in a vector substantially parallel to the plane of the layers. Next a low refractive index coupling layer 3103 and/or evanescent wave coupling layer comprising a low refractive and relatively thin thickness to allow photon tunneling in the said photonic band gap structure. Next another absorptive optoelectronic layer 3104 showing thicker material thickness to support longer wavelength guided mode 3112. To complete the optical confinement an upper cladding layer 3105 is disposed upon layer 3104.

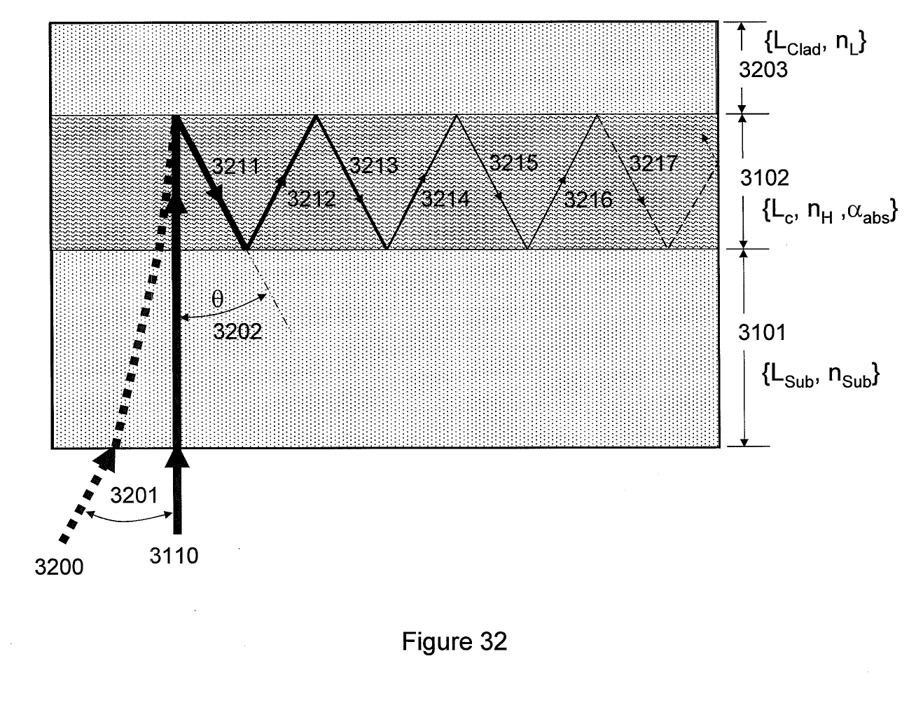

FIG. 32 further depicts possible variation of incident solar radiation angle 3220 (off-normal) and 3110 (normal) to the sapphire substrate. Entrance angle of solar radiation will depend on the wavelength dependence of the refractive index for each material. As sapphire is transparent to solar radiation without any absorption anomaly, wavelength dependence will be substantially determined by the guide design parameters 3101, 3102 and 3203, where L_{sub}=substrate thickness, n_{sub}=substrate refractive index, L_{C}=core or guiding layer thickness, α_{abs}=active layer wavelength dependent absorption co-efficient, n_{H}=active layer wavelength dependent refractive index, L_{Clad}=upper cladding layer (optical confinement) thickness, and n_{L}=upper cladding layer refractive index.

In one embodiment substantially planar solar cells and modules are placed in operation with an exposed sapphire substrate surface facing the sun at maximum power angle. Optionally, for fixed panels, off-normal solar radiation may be used advantageously for guiding solar radiation with the solar cell and/or module. Therefore, multi-spectral and multi-angle coverage are optional features of devices disclosed herein.

In all embodiments herein, a “substrate” may be an original substrate or replacement substrate; a “substrate” may be transparent to a majority of the radiation for converting or not. As used herein an active layer comprises one or more layers of semiconducting, insulative and/or metallic materials sufficient to enable a solar cell or other thin film solid state device as disclosed herein. An “active layer” may be fabricated originally on a substrate different than a replacement substrate; in some embodiments an active layer is transferred to a replacement substrate by a method disclosed herein or by reference disclosed herein or by techniques known to one knowledgeable in the art. As used herein a replacement or alternative substrate is optionally a substrate chosen from a group comprising glass, alkali-silicate glass, sapphire, plastics, including polyimide and Kapton, flexible plastics, insulative coated metal, ceramic, recycled silicon wafers, silicon ribbon, poly-silicon wafers or substrates and other low cost substrates known to one knowledgeable in the art.

In one embodiment a device for converting radiation to electrical energy comprises an active layer for the converting radiation to electrical energy; and a substrate, wherein the active layer comprises one or more rare-earth ions and, optionally, a barrier layer comprising at least one rare earth compound separating the active layer and the substrate substantially preventing material migration from the substrate to the active layer; optionally, the active layer comprises at least one lateral p-n junction; optionally, the substrate, comprises an electrical contact to the active layer; optionally, the active layer comprises at least two lateral p-n-p junctions; optionally, the active layer comprises at least one lateral p-n junctions and multiple p+and/or n+contacts to the active layer; optionally, the active layer comprises at least one vertical p-i-n structure; optionally, the active layer comprises at least one lateral p-i-n structure. In one embodiment a device for converting radiation to electrical energy comprises a MIS device on SoS. In one embodiment an active layer comprises comprises one or more rare-earth ions and, optionally, at least two lateral p-n-p junctions, and/or at least one vertical p-i-n structure, and/or at least one lateral p-i-n structure, and/or a MIS device.

An integrated device for converting radiation to electrical energy comprises a substrate; one or more active layers for the converting radiation to electrical energy comprising multiple devices interconnected; a plurality of devices for supplying a voltage; and a plurality of devices for supplying a current; optionally, the active layer comprises one or more rare-earth ions and, optionally, a barrier layer comprising at least one rare earth separating the active layer and substrate.

In one embodiment a device for converting radiation to electrical energy comprises a first portion of a first conductivity type at a first level of doping; a second portion of first conductivity type at a second level of doping less than the first, wherein a first drift voltage is imposed across the second portion; a third portion of first conductivity type at about the first level of doping; a fourth portion of first conductivity type at about the second level of doping, wherein a second drift voltage is imposed across the fourth portion; a fifth portion of second conductivity type at a third level of doping; such that the second portion is a drift region and the fourth portion is an avalanche region and electrons undergo avalanche multiplication in the avalanche region based upon the first drift voltage imposed across the second portion and the second drift voltage imposed across the fourth portion; a substrate; optionally, at least one portion comprises one or more rare-earth ions; alternatively, the first and second drift voltages are set as a function of the energy of said radiation being converted; alternatively, at least said second and fourth portions comprise a semiconductor material comprising an indirect band gap and a barrier layer comprising at least one rare earth separating the active layer and the substrate.

In one embodiment a device for converting radiation to electrical energy comprises a transparent substrate, a barrier layer and an active layer comprising a first portion of a first conductivity type at a first level of doping; a second portion of first conductivity type at a second level of doping less than the first, wherein a first drift voltage is imposed across the second portion; a third portion of second conductivity type at a third level of doping; such that the second portion is a drift and avalanche region wherein electrons undergo avalanche multiplication based upon the first drift voltage imposed across the second portion; alternatively, at least said second portion comprises a semiconductor material comprising an indirect band gap; optionally, at least one portion comprises one or more rare-earth ions; optionally said drift voltage is set as a function of the energy of said radiation being converted; optionally, at least about 50% of said electrical energy is converted from radiation of wavelength 400 nm and shorter and a barrier layer comprising at least one rare earth separating active layer and substrate.

A method for producing a thin film comprises the steps of providing a first substrate having a first surface and comprising a predetermined level of a first reactant therein; introducing ions of a second reactant into the first surface, such that the ions are distributed about a predetermined fracture depth; bonding a second substrate to the first surface of the first substrate; and heating the first and second substrates to a temperature sufficient for the first and second reactants to combine; optionally, applying mechanical forces to separate the first and second substrates about the fracture depth after said heating; in some embodiments the first and second reactants are chosen from a group comprising hydrogen, oxygen, nitrogen, carbon, fluorine, helium and silicon wherein, optionally, a barrier layer comprising at least one rare earth separates the first and second substrates.

A method for producing a thin film comprises the steps of providing a first substrate having a first surface; introducing ions of a first and second reactant into the first surface, such that the ions are distributed about a predetermined fracture depth; bonding a second substrate to the first surface of the first substrate; and heating the first and second substrates to a temperature sufficient for the first and second reactants to combine; optionally, applying mechanical forces to separate the first and second substrates about the fracture depth after said heating; in some embodiments an ion-exchange process is used for introducing said first and second reactant ions wherein a barrier layer comprising at least one rare earth separates the first and second substrates.

In one embodiment a device for converting radiation to electrical energy comprises a substrate; one or more layers of a large band gap material; and one or more layers of a small band gap material for converting radiation to electrical energy, such that one of the one or more layers of the large band gap material is contacting a layer of the small band gap material; the large band gap material is chosen from a group comprising one to three rare-earths [REₓRE_{y}RE_{z}], with at least one of oxygen, nitrogen and/or phosphorus; optionally, in combination with one or more of germanium, silicon, carbon; the large band gap material is described by the formula REₓRE_{y}RE_{z}SiₗGeₘCₙOᵤNᵥP_{w}, wherein at least one of u, v, or w is >0 and 0≦y, z, l, m, n, u, v, w ≦5 and 0<x≦5 and, optionally, a barrier layer comprising at least one rare earth separates the active layer and the substrate. .

In one embodiment a device for converting radiation to electrical energy comprises a substrate; one or more layers of a large band gap material; and one or more layers of a small band gap material for converting radiation to electrical energy, such that one of the one or more layers of the large band gap material is contacting a layer of the small band gap material; and the small band gap material is chosen from a group comprising rare-earth-silicon (REₓSi_{y}), rare-earth-germanium (REₓGe_{y}), rare-earth-phosphide (REₓP_{y}), rare-earth-nitride (REₓN_{y}) and a barrier layer comprising at least one rare earth separating the active layer and the substrate, optionally, a replacement substrate. In alternative embodiments a small band gap material is chosen from a composition described by the formula REₓRE_{y}RE_{z}SiₗGeₘCₙOᵤNᵥP_{w}, wherein at least one of l, m, n, u, v, or w is ≧0 and 0≦y, z, l, m, n, u, v, w≦5 and 0<x≦5.

In an embodiment a device for converting radiation to electrical energy comprises at least one single crystal Si thin film layer and one layer comprising a rare-earth in an active region and one layer comprising a rare-earth in a barrier layer. Optionally, said device comprises a sapphire substrate comprising aluminum atoms and various alkali ions wherein said barrier layer(s) prevents aluminum and alkali species from reaching active layer.

In alternate embodiments a device for converting radiation to electrical energy comprises a PIN device on SoS; alternatively a PINPIN dual diode on SoS using different thickness i-regions to efficiently absorb different portions of the solar spectrum is a device for converting radiation to electrical energy; alternatively, a MIS/PIN hybrid device on SoS is a device for converting radiation to electrical energy; alternatively, a SoS device with a barrier layer may be combined with one or more sun concentrators.

In some embodiments a device for converting radiation to electrical energy comprises a p-n, p-i-n, p-i-n-i-p, p-i-n-p-i-n, n-i-p-n-i-p, p-i-n-i-p or n-i-p-i-n, p-i-n-M-p-i-n-M-p-i-n, MIS/PIN hybrid, etc. and various combinations thereof. Alternative embodiments comprise fully-depleted Si-on-sapphire (FD-SoS) structures for MIS and/or SIS devices. All embodiments may comprise, optionally, one or more reflectors, one or more diffraction gratings, one or more layers functioning as photonic waveguides comprising diffractive elements with selected optical band gaps, one or more cladding layers, grating couplers and/or dispersive elements, chirped period gratings, 1-D photonic band gap gratings, and volume holograms, multilayer refractive index dispersion elements functioning to propagate radiation in a desired path or direction to increase adsorption.

In some embodiments a device for converting radiation to electrical energy comprises a substrate transparent to a majority of the radiation for converting; a barrier layer; and an active layer comprising multiple devices interconnected such that there are a plurality of devices for supplying a voltage, a plurality of devices for supplying a current and a plurality of devices for the converting radiation to electrical energy.

In some embodiments a thin film semiconductor is disposed upon a substrate, optionally sapphire, wherein the thin film semiconductor is separated from the substrate by a buffer layer; optionally the buffer layer may also function as a barrier layer; optionally the buffer layer is chosen from a group comprising single crystal aluminum oxide, silicon dioxide, a rare-earth based layer, or zinc oxide.

The present invention discloses the use of single crystal rare-earth based materials of the compositions REₓO_{y}N_{z}P_{w}Cᵥ; optionally, x>0 and 0≦y, z, w, v≦5, to seed the epitaxial growth of thin film semiconductor layer. Remnant defects from the epitaxy process may be removed via the implantation or incorporation of specific ion species and subsequent annealing and thermal oxidation process.

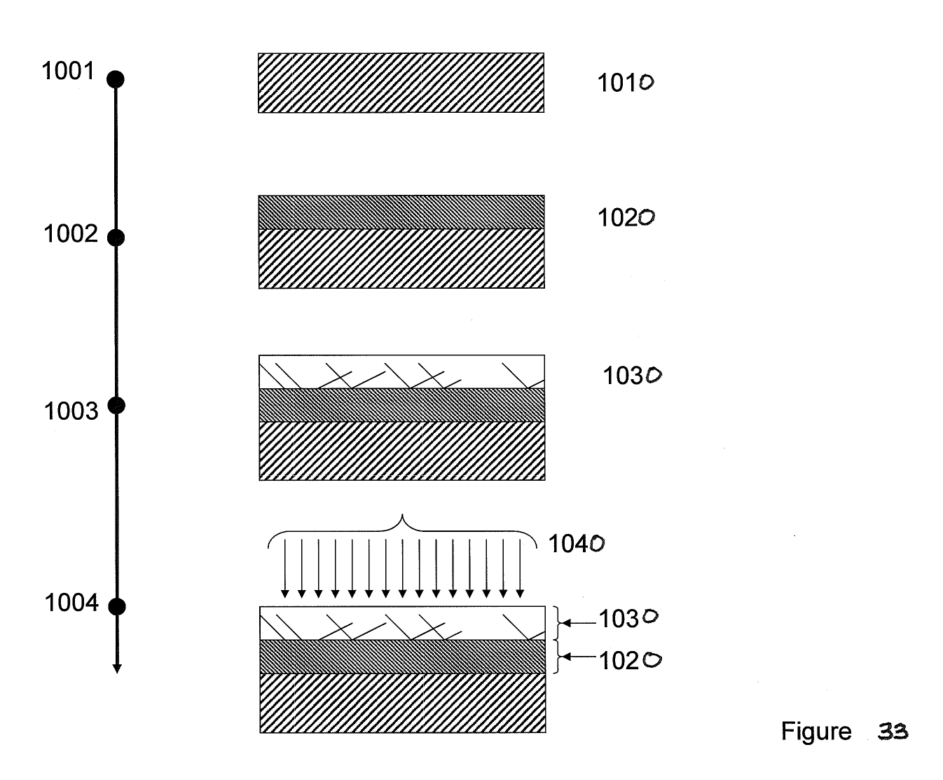

FIG. 33 discloses one embodiment of a process for manufacture of epitaxial semiconductor on rare-earth based layer. Step 1001 is the preparation of a single crystal substrate 101, (for example Si or Ge or sapphire Al₂O₃ or MgO or SiC). Next a single crystal rare-earth based layer 102 is epitaxially deposited upon substrate 101. 102 is chosen from REₓO_{y}N_{z}P_{w}Cᵥ type compounds; alternatively [RE1]ₘ[RE2]ₙ[RE1]ₚO_{y}N_{z}P_{w}Cᵥ[Si, Ge]x wherein 0<m and, optionally, 0≦n, p, x, y, z, w, v≦5, compounds may be chosen. For example, single crystal REOᵥ or REₓO_{y}N_{z} may be used. The rare-earth compound composition is chosen to exhibit insulating and or conducting electrical behavior. Next a crystalline thin film semiconductor layer 103 is epitaxially deposited upon rare-earth based layer 102. Alternatively a thin buffer layer of polycrystalline material may be deposited between a single crystal substrate and a next single crystal layer comprising a rare-earth; in some embodiments a polycrystalline buffer layer and a next single crystal growth layer are chosen from compositions comprising [RE1]ₘ[RE2]ₙ[RE1]ₚO_{y}N_{z}P_{w}Cᵥ[Si_{q}, Geᵣ, Cₛ]x, wherein m>0 and optionally, 0≦q, r, s, n, p, x, y, z, w, v≦5.

Thin film semiconductor may contain defects such as threading dislocations and twinning and the like. These defects are disadvantageous for high performance electronic devices. To remove these defects, step 1004 implants ions 104 into a region confined to region in immediate vicinity of rare-earth based layer and thin film semiconductor interface 105. The implanted region 105 is controlled so as to destroy long range crystal structure of thin film semiconductor within region 105 only. That is, the thin film semiconductor region 105 is converted to substantially amorphous form. The implanted ions are distributed with Gaussian depth profile 107. The species or implanted ions are chosen from elemental atoms comprising thin film semiconductor or oxygen or nitrogen or hydrogen; optionally, Si, Ge, C, O, H, He, P, F, Ar, K, Xe may be used.

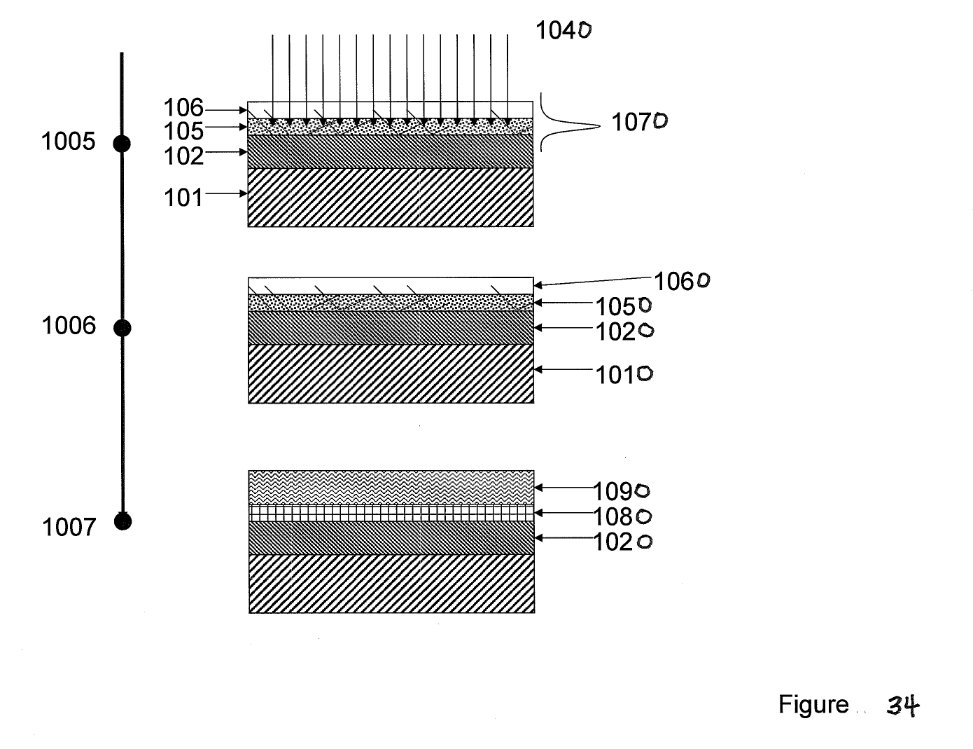

For example, in one embodiment, thin film semiconductor 103 is Silicon and implanted species 104 is chosen from Si ions. FIG. 34 shows, how an exemplary energy and time of implant is used to control 105 and the depth beneath the surface of 107. A remaining portion of relatively undamaged thin film semiconductor is shown as thin film semiconductor layer 106.

Step 1007, shows next a thermal annealing schedule is used in step 1006 to recrystallize solid phase layer 105 and form substantially “defect-free” single crystal thin film semiconductor in region 108. An anneal can be performed in oxidizing or nitriding or inert ambient such that, optionally, oxidation of remaining thin film semiconductor 106 is converted into new, or recrystallized, material 109. For example, thin film semiconductor 106 is silicon and oxidation with oxygen can create silicon oxide cap 109.

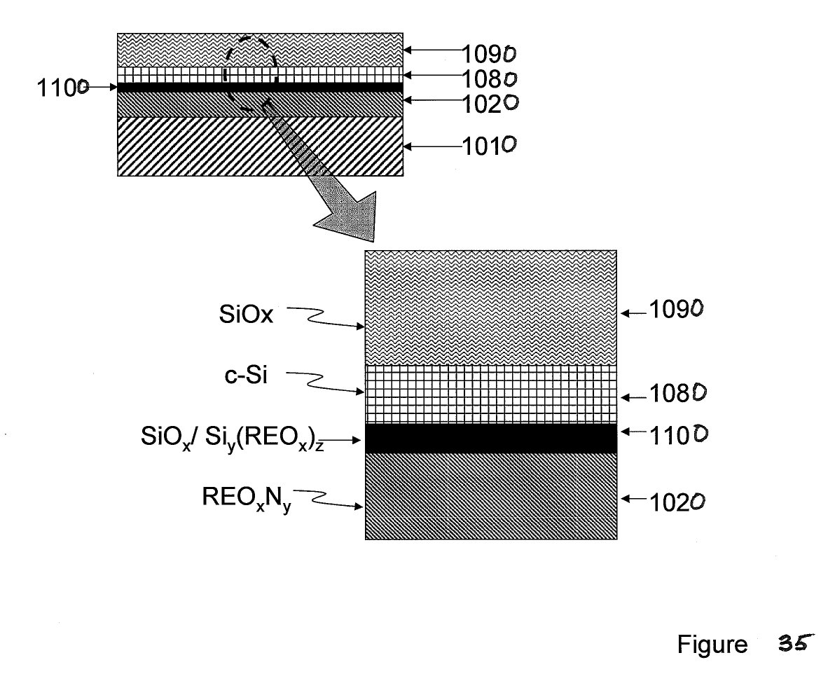

FIG. 35 shows detail of further modification of compound structure. During annealing and solid phase crystallization of 108, an interfacial layer may result forming another layer 110.

In one embodiment, layer 101 is chosen from single crystal Si or sapphire. Rare-earth based layer 102 is chosen from single crystal erbium-oxide. Thin film semiconductor 103 is chosen from S defect-free process of implantation of Si atoms 104. A thermal anneal, solid phase crystallization and oxidation result in layers 109 composed of SiO2, 108 composed of defect-free single crystal Si, and interfacial layer 110 composed of silicon oxide or ternary oxide of form Siy(REOx)z. An underlying rare-earth oxide layer 102 may remain unchanged or be enriched, optionally, depleted, with oxygen or silicon. The disclosed process produces “defect free” thin films, optionally fully depleted, semiconductor-on-insulator or conductor article or substrate or layer. As used herein, “defect free” means that an overall concentration of defects is below a critical number that impairs functionality of an intended device. In some embodiments this defect level may be less than 10^{2O}/cm³; in alternative embodiments the defect level may be less than 10¹⁶/cm³; in alternative embodiments the defect level may be less than 10¹⁴/cm³; in alternative embodiments the defect level may be less than 10¹²/cm³.

A method of manufacture for thin film semiconductor-on-insulator and semiconductor-on-conductor articles using rare-earth based insulator and or conductor. A thin film epitaxial and crystalline rare-earth layer is deposited upon single crystal substrate. A thin film semiconductor is deposited epitaxially upon a rare-earth based layer. Defects in an uppermost thin film semiconductor layer may be removed further via post growth processing using implantation of specific ion species in a region confined to a layer comprising at least one rare-earth specie and thin film semiconductor interface. Thermal annealing of an implanted article and, optionally, oxidation of a topmost epitaxial semiconductor layer is used to remove threading dislocations and or twins or other disadvantageous defects below a critical level for intended device performance.

Foregoing described embodiments of the invention are provided as illustrations and descriptions. They are not intended to limit the invention to precise form described. In particular, it is contemplated that functional implementation of invention described herein may be implemented equivalently. Alternative construction techniques and processes are apparent to one knowledgeable with integrated circuit, light emitting device, solar cell, flexible circuit and MEMS technologies. Other variations and embodiments are possible in light of above teachings, and it is thus intended that the scope of invention not be limited by this Detailed Description, but rather by Claims following.

I claim:

1. A device for converting radiation to electrical energy comprising;
an active layer for the converting radiation to electrical energy;
a barrier layer; and
a substrate transparent to a majority of the radiation for converting, wherein the active layer comprises at least one single crystal semiconductor layer and the barrier layer separates the active layer and the substrate such that migration of deleterious species across said barrier layer is functionally impeded.

2. A device as in claim 1 wherein said substrate is chosen from a group comprising sapphire, diamond (C₄), calcium fluoride (CaF₂), zircon (ZrₓSi₁₋ₓO₄), zinc oxide (ZnO), aluminum nitride (AlN), sodium-silicate glass (Na₂O)ₓ(SiO₂)₁₋ₓ and crystallized bauxite.

3. A device as in claim 1 wherein said barrier layer comprises one or more layers such that the one of the one or more layers in contact with said substrate is a template layer chosen from a group comprising Al₂O₃, N:Al₂O₃, aluminum oxynitride (AlOₓN_{y}), aluminum nitride (AlNₓ), silicon nitride (SiNₓ), silicon-aluminum-oxynitride (Si_{z}AlᵥOₓN_{y}), silicon-carbon-nitride (Si_{z}CₓN_{y}), aluminum-carbon-oxynitride (Al_{z}CᵥOₓN_{y}), silicon, SiOₓ and rare-earth material.

4. A device as in claim 1 wherein said at least one single crystal semiconductor layer comprises a composition chosen from at least one of silicon, germanium, carbon, rare-earth material or mixtures thereof.

5. A device as in claim 1 wherein said barrier layer comprises one or more layers of a rare-earth material comprising charged oxygen vacancies, (Oᵥⁿ), of a concentration at least 10¹⁴/cm³.

6. A device as in claim 1 wherein said barrier layer comprises a first layer of a rare-earth material of first orientation and a second layer of a rare-earth material of second orientation such that the first layer is in contact with said substrate and the second layer is in contact with said at least one single crystal semiconductor layer.

7. A device as in claim 1 wherein said active layer comprises a first layer of single crystal p-type silicon in contact with said barrier layer and a second layer comprising NID silicon and a third layer comprising n-type silicon such that a p-i-n diode is formed in said active region.

8. A device as in claim 1 wherein said active layer comprises a p-i-n-p-i-n stacked diode comprising;
a first layer of single crystal p-type silicon in contact with said barrier layer;
a second layer of NID silicon of first thickness;
a third layer of n-type silicon;
a fourth layer of p-type silicon;
a fifth layer of NID silicon of second thickness; and
a sixth layer of n-type silicon wherein the first thickness is less than about 20 nm and the second thickness is greater than about 100 nm.

9. A device as in claim 1 wherein said active layer comprises a dielectric-silicon-dielectric heterostructure comprising;
a first layer of a first rare-earth material in contact with said barrier layer;
a second layer of silicon of first thickness;
a third layer of a second rare-earth material; wherein the first and second rare-earth materials have a band gap about 2 eV or greater and the first thickness is less than about 50 nm.

10. A device for converting radiation to electrical energy comprising:
a substrate transparent to a majority of the radiation for converting;
a barrier layer; and
an active layer for the converting radiation to electrical energy comprising
a first portion of a first conductivity type at a first level of doping;
a second portion of first conductivity type at a second level of doping less than the first; and
a third portion of second conductivity type at a third level of doping; wherein a drift voltage is imposed across the second portion such that the second portion is a drift and avalanche region wherein electrons undergo avalanche multiplication based upon the drift voltage.

11. The device of claim 10 wherein said second portion comprises a semiconductor material comprising an indirect band gap.

12. The device of claim 10 wherein at least one portion comprises one or more rare-earth ions.

13. The device of claim 10 wherein said drift voltage is set as a function of the energy of said radiation being converted.

14. The device of claim 10 wherein at least about 50% of said electrical energy is converted from radiation of wavelength 400 nm and shorter.

15. A device for converting radiation to electrical energy comprising:
a substrate transparent to a majority of the radiation for converting;
a barrier layer; and
an active layer for the converting radiation to electrical energy comprising at least one lateral p-n junction.

16. A device for converting radiation to electrical energy as in claim 15 wherein the barrier layer comprises one or more rare-earth ions.

17. A device for converting radiation to electrical energy as in claim 15 wherein the substrate comprises an electrical contact to the active layer.

18. A device for converting radiation to electrical energy comprising:
a substrate transparent to a majority of the radiation for converting;
a barrier layer; and
an active layer for the converting radiation to electrical energy comprising at least two lateral p-n-p junctions.

19. A device for converting radiation to electrical energy as in claim 18 wherein the active layer comprises one or more rare-earth ions.

20. A device for converting radiation to electrical energy comprising:
a substrate transparent to a majority of the radiation for converting;
a barrier layer; and
an active layer comprising multiple devices interconnected such that there are a plurality of devices for supplying a voltage, a plurality of devices for supplying a current and a plurality of devices for the converting radiation to electrical energy.

21. A device as in claim 20 wherein said substrate is chosen from a group comprising sapphire, diamond (C₄), calcium fluoride (CaF₂), zircon (ZrₓSi₁₋ₓO₄), zinc oxide (ZnO), aluminum nitride (AlN), sodium-silicate glass (Na₂O)ₓ(SiO₂)₁₋ₓ and crystallized bauxite.

22. A device as in claim 20 wherein said barrier layer comprises one or more layers such that the one of the one or more layers in contact with said substrate is a template layer chosen from a group comprising Al₂O₃, N:Al₂O₃, aluminum oxynitride (AlOₓN_{y}), aluminum nitride (AlNₓ), silicon nitride (SiNₓ), silicon-aluminum-oxynitride (Si_{z}AlᵥOₓN_{y}), silicon-carbon-nitride (Si_{z}CₓN_{y}), aluminum-carbon-oxynitride (Al_{z}CᵥOₓN_{y}), silicon, SiOₓ and rare-earth material.

23. A device as in claim 20 wherein said active layer comprises at least one single crystal semiconductor layer comprising a composition chosen from at least one of silicon, germanium, carbon, rare-earth material or mixtures thereof.

24. A device as in claim 20 wherein said barrier layer comprises one or more layers of a rare-earth material comprising charged oxygen vacancies, (Oᵥⁿ), of a concentration at least 10¹⁴/cm³.

25. A device as in claim 20 wherein said barrier layer comprises a first layer of a rare-earth material of first orientation and a second layer of a rare-earth material of second orientation such that the first layer is in contact with said substrate and the second layer is in contact with said active layer.
